(19) United States
(12) Patent Application Publication
(10) Pub. No.: US 2025/0265979 A1
(43) Pub. Date: Aug. 21, 2025

(54) DISPLAY PANEL AND DISPLAY DEVICE

(71) Applicant: Wuhan Tianma Microelectronics Co., Ltd., Wuhan (CN)

(72) Inventors: Xu ZHAO, Wuhan Hubei (CN); Xianchi WANG, Wuhan (CN)

(73) Assignee: Wuhan Tianma Microelectronics Co., Ltd., Wuhan (CN)

(21) Appl. No.: 19/203,696

(22) Filed: May 9, 2025

(30) Foreign Application Priority Data
May 13, 2024 (CN) 202410592237.7

(51) Int. Cl. G09G 3/32; H10H 29/39; H10H 29/49

(52) U.S. Cl. CPC G09G 3/32; H10H 29/39; H10H 29/49; G09G 2300/0426; G09G 2300/0819; G09G 2300/0861; G09G 2310/0262; G09G 2310/0297; G09G 2310/08; G09G 2320/045

(57) ABSTRACT

A display region of a display panel includes first power signal lines and second power signal lines which are electrically connected, the first power signal lines extend in a first direction and are arranged in a second direction, and the second power signal lines extend in the second direction and are arranged in the first direction; where the first direction intersects the second direction. A non-display region of the display panel includes a first power bus line, and the first power signal lines are electrically connected to the first power bus line. The first power signal lines and the second power signal lines are electrically connected, and among two second power signal lines, a voltage in a second power signal line facing the first power bus line is different from a voltage in a second power signal line facing away from the first power bus line.

### CROSS-REFERENCE TO RELATED APPLICATION(S)

This application claims the priority of a Chinese Patent Application No. 202410592237.7, filed on May 13, 2024, the disclosure of which is incorporated herein by reference in its entirety.

### TECHNICAL FIELD

The present application relates to the field of display technology and, in particular, to a display panel and a display device.

### BACKGROUND

In related display panels, power signals are provided for pixel circuits through power signal lines. However, due to the resistance in the power signal lines, transmission loss exists during the transmission process of the power signals because of a voltage drop, which affects the uniformity of the power signals and thus affects the display uniformity of the display panel.

### SUMMARY

Embodiments of the present application provide a display panel and a display device.

In a first aspect, the embodiments of the present application provide a display panel, and the display panel includes a display region and multiple subpixels located in the display region.

The multiple subpixels include pixel circuits, the display panel further includes power signal lines located in the display region, and the power signal lines are electrically connected to the pixel circuits.

The power signal lines include first power signal lines and second power signal lines which are electrically connected, the first power signal lines extend in a first direction and are arranged in a second direction, and the second power signal lines extend in the second direction and are arranged in the first direction, where the first direction intersects the second direction.

The display panel further includes a non-display region located on a side of the display region and a first power bus line located in the non-display region, where the first power signal lines are electrically connected to the first power bus line; among two second power signal lines of the second power signal lines, a voltage in a second power signal line facing the first power bus line is different from a voltage in a second power signal line facing away from the first power bus line.

In a second aspect, the embodiments of the present application further provide a display device, and the display device includes a display panel, and the display panel includes a display region and multiple subpixels located in the display region. The multiple subpixels include pixel circuits, the display panel further includes power signal lines located in the display region, and the power signal lines are electrically connected to the pixel circuits. The power signal lines include first power signal lines and second power signal lines which are electrically connected, the first power signal lines extend in a first direction and are arranged in a second direction, and the second power signal lines extend in the second direction and are arranged in the first direction, where the first direction intersects the second direction. The display panel further includes a non-display region located on a side of the display region and a first power bus line located in the non-display region, where the first power signal lines are electrically connected to the first power bus line; among two second power signal lines of the second power signal lines, a voltage in a second power signal line facing the first power bus line is different from a voltage in a second power signal line facing away from the first power bus line.

### BRIEF DESCRIPTION OF DRAWINGS

FIG. 1 is a structural diagram of a display panel according to embodiments of the present application;

FIG. 2 is a structural diagram of another display panel according to embodiments of the present application;

FIG. 3 is a structural diagram of another display panel according to embodiments of the present application;

FIG. 4 is a structural diagram of another display panel according to embodiments of the present application;

FIG. 5 is a structural diagram of a pixel circuit according to embodiments of the present application;

FIG. 6 is a working timing diagram of a pixel circuit according to embodiments of the present application;

FIG. 7 is a structural diagram of another display panel according to embodiments of the present application;

FIG. 8 is a structural diagram of another pixel circuit according to embodiments of the present application;

FIG. 9 is a structural diagram illustrating the layout of a pixel circuit according to embodiments of the present application;

FIG. 10 is a structural diagram of another pixel circuit according to embodiments of the present application;

FIG. 11 is a structural diagram illustrating the layout of a pixel circuit according to embodiments of the present application;

FIG. 12 is a structural diagram of another display panel according to embodiments of the present application;

FIG. 13 is a structural diagram of another display panel according to embodiments of the present application;

FIG. 14 is a structural diagram of another display panel according to embodiments of the present application;

FIG. 15 is a structural diagram of another display panel according to embodiments of the present application;

FIG. 16 is a structural diagram of another display panel according to embodiments of the present application;

FIG. 17 is a structural diagram of another display panel according to embodiments of the present application;

FIG. 18 is a structural diagram of another display panel according to embodiments of the present application;

FIG. 19 is a structural diagram of another display panel according to embodiments of the present application;

FIG. 20 is a structural diagram illustrating the layout of another pixel circuit according to embodiments of the present application; and

FIG. 21 is a structural diagram of a display device according to embodiments of the present application.

### DETAILED DESCRIPTION

To make the objects, solutions and advantages of the present application clearer, the technical solutions of the present application will be completely described below in conjunction with the specific embodiments and the drawings in the embodiments of the present application.

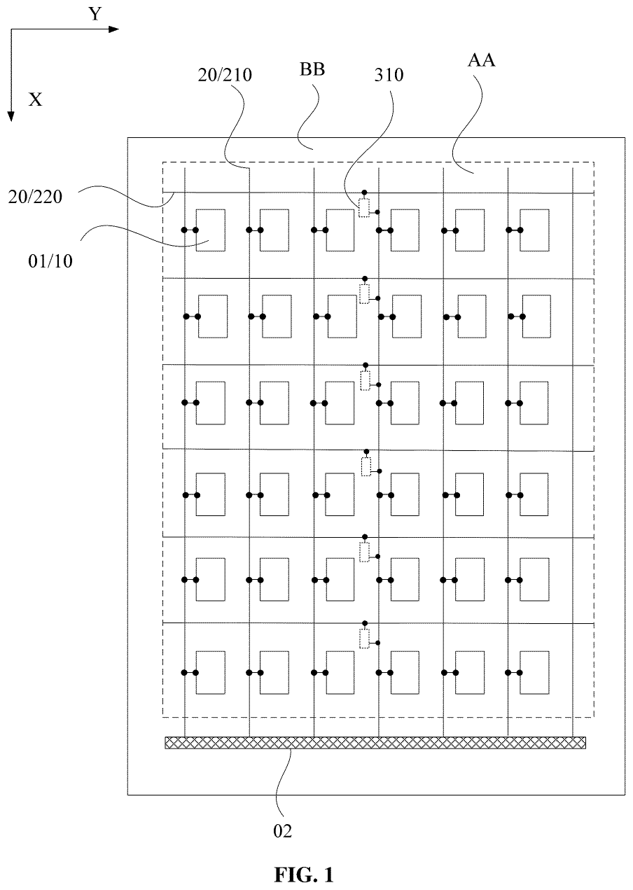

FIG. 1 is a structural diagram of a display panel according to embodiments of the present application. Referring to FIG. 1, the display panel provided in the embodiments of the present application includes a display region AA and multiple subpixels 01 located in the display region. The subpixels 01 include pixel circuits 10. The display panel further includes power signal lines 20 located in the display region AA. The power signal lines 20 are electrically connected to the pixel circuits 10. The power signal lines 20 include first power signal lines 210 and second power signal lines 220 which are electrically connected, the first power signal lines 210 extend in a first direction X and are arranged in a second direction Y, and the second power signal lines 220 extend in the second direction Y and are arranged in the first direction X, where the first direction X intersects the second direction Y. The display panel further includes a non-display region BB located on a side of the display region AA and a first power bus line 02 located in the non-display region BB. The first power signal lines 210 are electrically connected to the first power bus line 02. Among two second power signal lines 220, a voltage in a second power signal line 220 facing the first power bus line 02 is different from a voltage in a second power signal line 220 facing away from the first power bus line 02.

Illustratively, as shown in FIG. 1, the display region AA of the display panel includes multiple subpixels 01, each of the subpixels 01 includes a light-emitting device and a pixel circuit 10, and the pixel circuit 10 is electrically connected to the light-emitting device. A drive signal is provided through the pixel circuit 10 for the light-emitting device to drive the light-emitting device to emit light, and thus the display of an image is achieved. Multiple pixel circuits 10 may be arranged in an array in the first direction X and the second direction Y which intersect. Further, the display region AA includes the power signal lines 20. The power signal lines 20 are electrically connected to the pixel circuits 10 so that power signals are provided for the pixel circuits 10 through the power signal lines 20. The power signal lines 20 include the first power signal lines 210. The first power signal lines 210 extend in the first direction X and are arranged in the second direction Y, that is, the first power signal lines 210 extend longitudinally and are arranged horizontally. The first power signal lines 210 may be positive power signal lines or negative power signal lines. Moreover, the display panel further includes the non-display region BB located on the side of the display region AA. Exemplarily, the non-display region BB may be a bezel region of the display panel, for example, a left bezel region, a right bezel region, a top bezel region or a bottom bezel region. The non-display region BB includes the first power bus line 02. The first power signal lines 210 are electrically connected to the first power bus line 02, the first power signal lines 210 are electrically connected to the pixel circuits 10, and then the first power bus line 02 provides positive power signals or negative power signals for the pixel circuits 10 through the first power signal lines 210.

A voltage drop exists during the signal transmission process of a first power signal line 210, that is, in the first power signal line 210, a voltage difference exists between a side of the first power signal line 210 facing the first power bus line 02 and a side of the first power signal line 210 facing away from the first power bus line 02. For example, when the first power bus line 02 is located in the bottom bezel region of the non-display region and provides a positive power signal for the first power signal line, the voltage drop may lead to that a voltage of the side of the first power signal line 210 facing the first power bus line 02 is larger than the voltage of the side of the first power signal line 210 facing away from the first power bus line 02, that is, may lead to the voltage difference, affecting the display uniformity of the display panel.

In view of this, in the embodiments of the present application, the power signal lines 20 include the second power signal lines 220, and the second power signal lines 220 extend in the second direction Y and are arranged in the first direction X. The second power signal lines 220 may be positive power signal lines or negative power signal lines, and power signals transmitted in the second power signal lines 220 have the same polarity as power signals transmitted in the first power signal lines 210, that is, the power signals transmitted in the second power signal lines 220 and the power signals transmitted in the first power signal lines 210 are both positive power signals or negative power signals. That is, the first power signal lines 210 are positive power signal lines, and the second power signal lines 220 are positive power signal lines; or the first power signal lines 210 are negative power signal lines, and the second power signal lines 220 are negative power signal lines. The second power signal lines 220 are electrically connected to the first power signal lines 210 and are configured to transmit compensation signals transmitted on the second power signal lines 220 to the first power signal lines 210.

It is to be noted that the electrical connections between the first power signal lines 210 and the second power signal lines 220 are not the direct connection achieved by punching holes or through contact at the intersections between the first power signal lines 210 and the second power signal lines 220, but the indirect electrical connections between the first power signal lines 210 and the second power signal lines 220 achieved through other devices. For example, the electrical connections between the first power signal lines 210 and the second power signal lines 220 are achieved through the switch elements 310 shown in FIG. 1. Further, the second power signal lines 220 are not configured to form a grid of power signal lines arranged horizontally or longitudinally and in parallel with the first power signal lines 210. The second power signal lines 220 are configured to compensate for signal loss caused by signal line impedance at different positions in the extension direction of the same first power signal line 210, so as to ensure that the same first power signal line has the same power signal or similar power signals at different positions in the extension direction, ensure the uniformity of the power signal, and ensure the overall display uniformity of the display panel. Moreover, the power signals in the second power signal lines 220 are not obtained through the first power signal lines 210, or in other words, the power signals in the second power signal lines 220 are not obtained through the first power bus line 02, and the second power signal lines 220 have a power signal source independent of the first power signal lines 210. In this manner, it can be ensured that power signals transmitted in second power signal lines 220 at different positions can have a difference in achieving voltage compensation for different positions in the extension direction of the same first power signal line 210. Moreover, the difference between power signals in different second power signal lines 220 comes from the difference between power signals provided by the power signal source, rather than comes from the difference caused by impedance during the signal transmission process. It is to be understood that the first power signal lines 210 and the second power signal lines 220 are not always in an electrically connected state. For example, a first power signal line 210 has a first position and a second position which are different in the extension direction, and a compensation voltage corresponding to the first position and a compensation voltage corresponding to the second position are different. When voltage compensation is required at the first position, a second power signal line 220 corresponding to the first position will be electrically connected to the first power signal line 210 through a switch element 310 to transmit the compensation voltage, and a second power signal line 220 corresponding to the second position is not electrically connected to the first power signal line 210. When voltage compensation is required at the second position, a second power signal line 220 corresponding to the second position will be electrically connected to the first power signal line 210 through a switch element 310 to transmit the compensation voltage, and the second power signal line 220 corresponding to the first position is not electrically connected to the first power signal line 210.

Moreover, the voltage difference exists between a side of the first power signal line 210 facing the first power bus line 02 and a side of the first power signal line 210 facing away from the first power bus line 02, so the voltage of the power signal in a second power signal line 220 facing the first power bus line 02 is set to be different from the voltage of the power signal in a second power signal line 220 facing away from the first power bus line 02. In this manner, the voltage in the second power signal line 220 facing the first power bus line 02 compensates for the voltage at a position of the first power signal line 210 facing the first power bus line 02, and the voltage in the second power signal line 220 facing away from the first power bus line 02 compensates for the voltage at a position of the first power signal line 210 facing away from the first power bus line 02, so the voltage difference is reduced between the side of the first power signal line 210 facing the first power bus line 02 and the side of the first power signal line 210 facing away from the first power bus line 02. In other words, different voltages in second power signal lines 220 at different positions compensate for the voltage difference caused by the voltage drop in the first power signal line 210 in the first direction X, so the uniformity of the voltage in each of the first power signal lines 210 in the first direction X is improved, and the display effect of the display panel is improved.

It is to be noted that FIG. 1 only exemplarily illustrates, but does not limit, the example where the first power bus line 02 is located in the bottom bezel region of the display panel, which is not limited in the embodiments of the present application. In other embodiments, the first power bus line 02 may also be located in the top bezel region of the display panel. The position of the first power bus line 02 may be set by those skilled in the art as needed.

In summary, in the embodiments of the present application, the first power signal lines and the second power signal lines are electrically connected, and among two second power signal lines, the voltage in the second power signal line facing the first power bus line is different from the voltage in the second power signal line facing away from the first power bus line. In this manner, the voltage in the second power signal line facing the first power bus line compensates for the voltage at the position of the first power signal line facing the first power bus line, and the voltage in the second power signal line facing away from the first power bus line compensates for the voltage at the position of the first power signal line facing away from the first power bus line, so the voltage difference is reduced between the side of the first power signal line facing the first power bus line and the side of the first power signal line facing away from the first power bus line. In other words, different voltages in second power signal lines at different positions compensate for the voltage difference caused by the voltage drop in each of the first power signal lines in the first direction, so the uniformity of the voltage in the first power signal lines in the first direction is improved, and the display effect of the display panel is improved.

In some embodiments, on the basis of the preceding embodiments, referring to FIG. 1, the voltage in the second power signal line 220 facing the first power bus line 02 is smaller than the voltage in the second power signal line 220 facing away from the first power bus line 02.

In the implementation shown in FIG. 1, the first power bus line 02 is located in the bottom bezel region of the display panel, and the first power bus line 02 provides a positive power signal for the pixel circuits 10 through the first power signal lines 210. In this case, the voltage of the side of the first power signal line 210 facing the first power bus line 02 is larger than the voltage of the side of the first power signal line 210 facing away from the first power bus line 02. Then, two second power signal lines are set. Among the two second power signal lines, the voltage of the power signal in the second power signal line 220 facing the first power bus line 02 is smaller than the voltage of the power signal in the second power signal line 220 facing away from the first power bus line 02. In this manner, the smaller voltage in the second power signal line 220 facing the first power bus line 02 compensates for the lower voltage loss caused by the smaller voltage drop on the side of the first power signal line 210 facing the first power bus line 02, and the larger voltage in the second power signal line 220 facing away from the first power bus line 02 compensates for the higher voltage loss caused by the larger voltage drop on the side of the first power signal line 210 facing away from the first power bus line 02, so the voltage difference is reduced between the side of the first power signal line 210 facing the first power bus line 02 and the side of the first power signal line 210 facing away from the first power bus line 02, the uniformity of the voltage in the first power signal line 210 in the first direction X is improved, and the display effect of the display panel is improved.

It is to be noted that the preceding embodiments exemplarily illustrate, but do not limit, the example where the first power bus line 02 provides a positive power signal for the pixel circuits 10 through the first power signal lines 210. In other embodiments, the first power bus line 02 may provide a negative power signal for the pixel circuits 10 through the first power signal lines 210. In this case, the voltage drop will cause the voltage of the side of the first power signal line 210 facing the first power bus line 02 to be smaller than the voltage of the side of the first power signal line 210 facing away from the first power bus line 02. In view of this, it is necessary to set two second power signal lines, and among the two second power signal lines, the voltage of the power signal in the second power signal line 220 facing the first power bus line 02 is larger than the voltage of the power signal in the second power signal line 220 facing away from the first power bus line 02. These embodiments have the same effect as the preceding embodiments, which is not repeated here.

In some embodiments, on the basis of the preceding embodiments, with continued reference to FIG. 1, a signal transmitted on the second power signal lines 220 is a fixed potential signal. Illustratively, the second power signal lines 220 may be electrically connected to a fixed potential terminal so that a fixed potential signal is transmitted on the second power signal lines 220. It is to be noted that the source of the fixed potential signal transmitted on the second power signal lines 220 is different from the source of the power signal transmitted on the first power signal lines 210, that is, the fixed potential terminal is a structure different from the first power bus line 02, which ensures that when the first power signal lines 210 are electrically connected to the second power signal lines 220 indirectly, the voltage of the fixed potential signal transmitted on the second power signal lines 220 can serve as the compensation to the voltage in the first power signal line 210. It is to be understood that the second power signal lines 220 transmitting the fixed potential signal does not mean that signals transmitted on all of the second power signal lines 220 have the same voltage, but rather means that the voltage signal transmitted on one second power signal line 220 is a fixed potential signal rather than an alternating current (AC) signal.

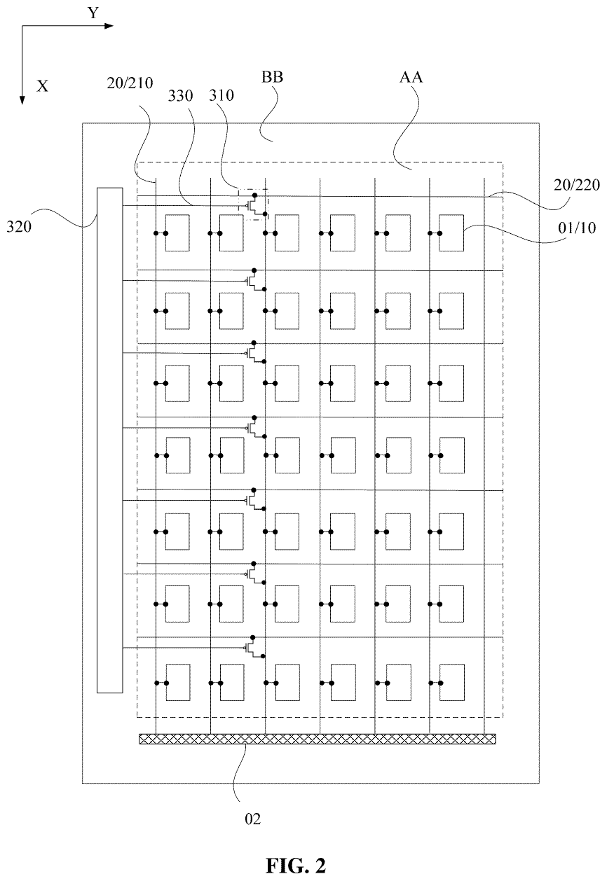

In some embodiments, FIG. 2 is a structural diagram of another display panel according to embodiments of the present application. As shown in FIG. 2, the display panel further includes multiple switch elements 310 located in the display region AA, multiple switch signal lines 330 located in the display region AA, and a switch driver circuit 320 located in the non-display region BB. A first terminal of a switch element 310 is electrically connected to a second power signal line 220, a second terminal of the switch element 310 is electrically connected to a first power signal line 210, and a control terminal of the switch element 310 is electrically connected to a switch signal line 330. The switch signal line 330 is electrically connected to the switch driver circuit 320 for receiving a switch signal provided by the switch driver circuit 320. The switch element 310 is configured to make the first power signal line 210 electrically connect to the second power signal line 220 under the control of the switch signal.

Illustratively, the display panel further includes multiple switch elements 310 located in the display region AA and multiple switch signal lines 330 located in the display region AA. Exemplarily, in the implementation shown in FIG. 2, the number of switch elements 310 is equal to the number of second power signal lines 220, and the switch elements 310 are set in one-to-one correspondence with the second power signal lines 220. The number of switch elements 310 is equal to the number of switch signal lines 330, and the switch elements 310 are set in one-to-one correspondence with the switch signal lines 330. The display panel further includes the switch driver circuit 320 located in the non-display region BB, and the switch driver circuit 320 may be located in the left bezel region and/or right bezel region of the non-display region BB. The switch driver circuit 320 is electrically connected to the control terminals of corresponding switch elements 310 through switch signal lines 330 so that a switch signal is provided for the control terminals of the switch elements 310 through the switch driver circuit 320. The first terminal of the switch element 310 may be an input terminal, and the second terminal of the switch element 310 may be an output terminal. The first terminal of the switch element 310 is electrically connected to the second power signal line 220, and the second terminal of the switch element 310 is electrically connected to the first power signal line 210. When the switch element 310 is turned on under the action of the switch signal, the voltage of the power signal in the second power signal line 220 serves as the compensation to the first power signal line 210. When the switch element 310 is turned off under the action of the switch signal, the first power signal line 210 keeps an original voltage. Moreover, when the switch elements 310 are set in one-to-one correspondence with the second power signal lines 220, after the voltage in the second power signal lines 220 is transmitted through the switch elements 310 to the first power signal lines 210 electrically connected to the switch elements 310, the first power signal lines 210 transmit the compensated voltage to the first power bus line 02, and then the first power bus line 02 transmits the compensated voltage to each first power signal line 210, so voltage compensation for each first power signal line 210 is achieved. In this manner, on the basis that the problem is solved of the voltage difference caused by the voltage drop in each first power signal line 210, compensation control is achieved through the switch elements 210 and the switch signal lines 330, and compensation signals of different sizes are provided for different positions of each of the first power signal lines through the switch elements 210 and the switch signals.

It is to be noted that the switch driver circuit 320 may provide the switch signal for the multiple switch signal lines 330 line by line. For example, after providing the switch signal for the switch element 310 corresponding to the first switch signal line, then the switch driver circuit 320 provides the switch signal for the switch element 310 corresponding to the second switch signal line, and so on, that is, the switch driver circuit 320 outputs the switch signal line by line.

It is further to be noted that FIG. 2 only exemplarily illustrates, but does not limit, the example where the switch elements 310 are set in one-to-one correspondence with the second power signal lines 220. In other embodiments, the number of switch elements 310 may be larger than the number of second power signal lines 220, and multiple switch elements 310 may be set for the same power signal line 220, which may be set by those skilled in the art as needed.

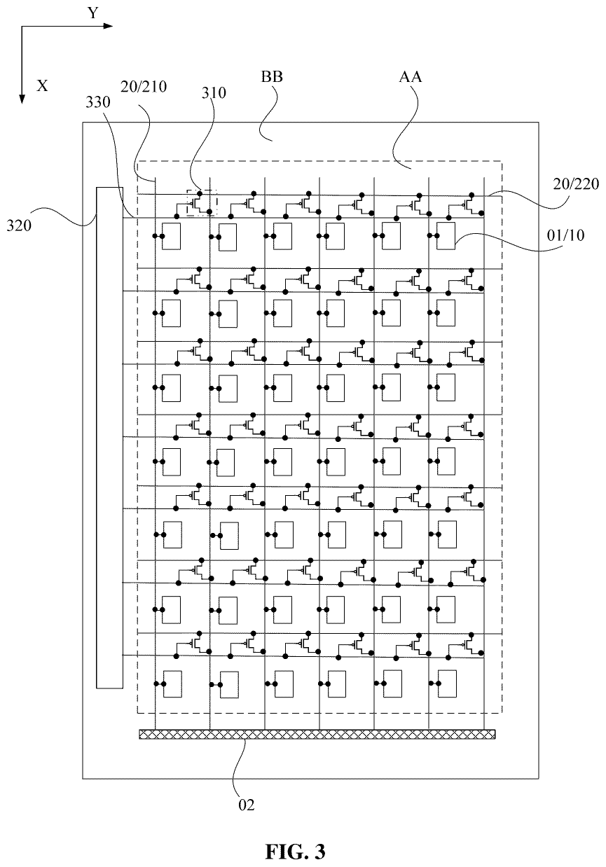

In other embodiments, FIG. 3 is a structural diagram of another display panel according to embodiments of the present application. In the implementation shown in FIG. 3, the multiple switch elements 310 are arranged in an array in the first direction X and the second direction Y. First terminals of multiple switch elements 310 arranged in the second direction Y are electrically connected to the same second power signal line 220, second terminals of the multiple switch elements 310 arranged in the second direction Y correspond to the first power signal lines 210 and are electrically connected to the first power signal lines 210, and control terminals of the multiple switch elements 310 arranged in the second direction Y are electrically connected to the same switch signal line 330. Moreover, first terminals of multiple switch elements 310 arranged in the first direction X correspond to the second power signal lines 220 and are electrically connected to the second power signal lines 220, second terminals of the multiple switch elements 310 arranged in the first direction X are electrically connected to the same first power signal line 210, and control terminals of the multiple switch elements 310 arranged in the first direction X correspond to the switch signal lines 330 and are electrically connected to the switch signal lines 330. In this manner, the multiple switch elements 310 arranged in the second direction Y provide the compensation voltage for the same position on all of the first power signal lines 210 under the control of the switch signal in the same switch signal line 330. The multiple switch elements 310 arranged in the first direction X provide the compensation voltage for different positions on the same first power signal line 210 under the control of the switch signals in corresponding switch signal lines 330.

Exemplarily, in the implementation shown in FIG. 3, the multiple switch elements 310 arranged in an array are set in one-to-one correspondence with the subpixels 01, so each first power signal line 210 has a switch element 310 for achieving electrical connection at a position corresponding to a second power signal line 220 corresponding to the each first power signal line 210, and each first power signal line 210 has a second power signal line 220 for voltage compensation at a position corresponding to a switch element 310 corresponding to each first power signal line 210. Compared with the scheme where the switch elements 310 are set in one-to-one correspondence with the second power signal lines 220, this scheme can achieve precise and fast compensation for each first power signal line 210, so the uniformity of the voltage in the first power signal lines 210 is improved, and the display effect of the display panel is improved.

It is to be noted that the embodiments of the present application only exemplarily illustrate, but do not limit, the example where the switch elements 310 are set in one-to-one correspondence with the subpixels 01. In other implementations, one switch element 310 may correspond to multiple subpixels 01, or multiple switch elements 310 may correspond to one subpixel 01, which may be set by those skilled in the art as needed.

In some embodiments, on the basis of the preceding embodiments, with continued reference to FIG. 3, the switch element 310 includes a switch transistor. Illustratively, the switch transistor has the characteristics of low power consumption and fast response. It is set that the switch element 310 includes the switch transistor, so fast compensation for the first power signal lines 310 can be further achieved. Moreover, the switch transistor may include a PNP type transistor or an NPN type transistor. If the switch transistor is a PNP type transistor, the switch element 310 is turned on at a low level signal and is turned off at a high level signal. If the switch transistor is an NPN type transistor, the switch element 310 is turned on at a high level signal and is turned off at a low level signal. The embodiments of the present application do not limit the specific type of the switch transistor, and those skilled in the art may set the type of the switch transistor as needed.

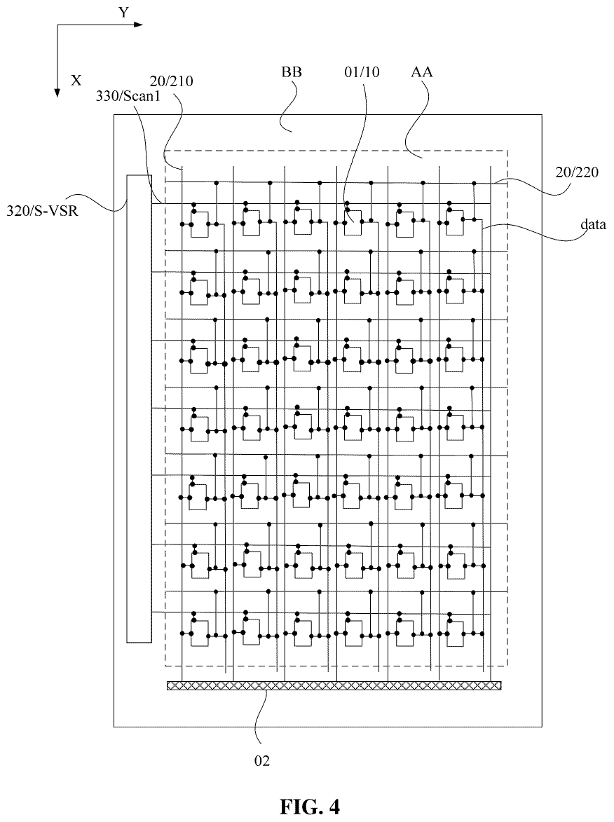

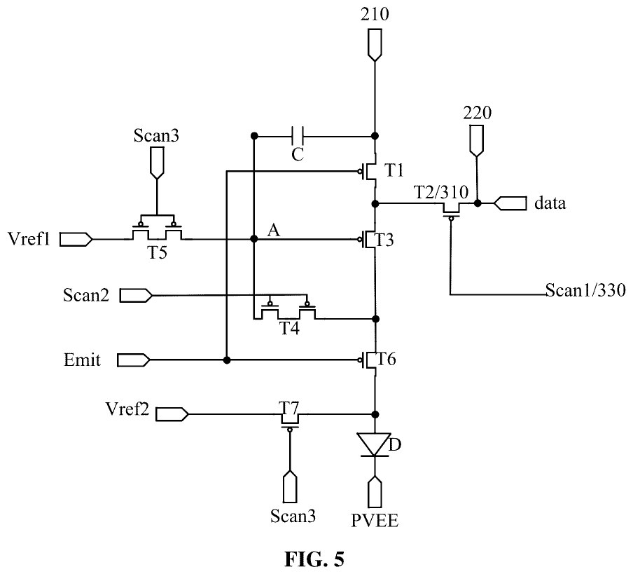

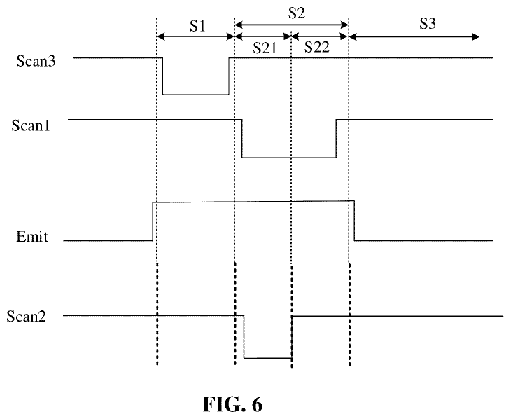

In some embodiments, FIG. 4 is a structural diagram of another display panel according to embodiments of the present application, FIG. 5 is a structural diagram of a pixel circuit according to embodiments of the present application, and FIG. 6 is a working timing diagram of a pixel circuit according to embodiments of the present application. Referring to FIG. 4, FIG. 5 and FIG. 6, a pixel circuit 10 includes a drive transistor T3 and a data write transistor T2. The display panel further includes one or more data signal lines data, one or more first scan signal lines Scan1 and a scan driver circuit S-VSR, the data signal lines data and the first scan signal lines Scan1 are located in the display region AA, and the scan driver circuit S-VSR is located in the non-display region BB. A first terminal of the data write transistor T2 is electrically connected to a data signal line data, a second terminal of the data write transistor T2 is electrically connected to a first terminal of the drive transistor T3, and a control terminal of the data write transistor T2 is electrically connected to a first scan signal line Scan1. The first scan signal line Scan1 is electrically connected to the scan driver circuit S-VSR and is configured to receive a first scan signal provided by the scan driver circuit S-VSR. The data write transistor T2 is configured to output a data signal provided by the data signal line data to the first terminal of the drive transistor T3 under the control of the first scan signal. The switch element 310 also serves as the data write transistor T2, the switch signal line 330 also serves as the first scan signal line Scan1, and the switch driver circuit 320 also serves as the scan driver circuit S-VSR. An enable stage S2 of the first scan signal includes a first enable stage S21 and a second enable stage S22. In the first enable stage S21, the data signal is transmitted through the data write transistor T2 to the first terminal of the drive transistor T3. In the second enable stage S22, the voltage signal provided by the second power signal line 220 is transmitted through the data write transistor T2 to the first terminal of the drive transistor T3.

Illustratively, the display panel further includes a shift register located in the non-display region BB. Exemplarily, as shown in FIG. 4, the shift register may be located in the left bezel region and/or right bezel region of the display panel. The shift register includes multiple cascaded shift register circuits, and the shift register circuit may include a scan driver circuit S-VSR. The scan driver circuit S-VSR is electrically connected to pixel circuits 10 through the first scan signal line Scan1 and is configured to provide the first scan signal for the pixel circuits 10. Moreover, a clock signal line, a high level signal line and a low level signal line may further be included between the scan driver circuit S-VSR and a driver chip located in the bottom bezel region of the display panel. The driver chip provides a clock signal, a high level signal and a low level signal for the scan driver circuit S-VSR to ensure that the scan driver circuit S-VSR can normally output the first scan signal to the first scan signal lines Scan1.

Moreover, FIG. 5 exemplarily shows that the pixel circuit 10 includes seven thin-film transistors and one storage capacitor, that is, the pixel circuit 10 is a 7T1C circuit, for illustration purposes. Referring to FIG. 4, FIG. 5 and FIG. 6, the working process of the pixel circuit 10 is briefly illustrated. Referring to FIG. 4 and FIG. 5, any row of pixel circuits is taken as an example. The pixel circuit 10 includes the drive transistor T3 and the data write transistor T2. The pixel circuit 10 further includes a second light emission control transistor T1, an initialization transistor T5, a first light emission control transistor T6, a threshold compensation transistor T4 and a reset transistor T7. A first terminal of the second light emission control transistor T1 is electrically connected to a first power signal line 210, and a second terminal of the second light emission control transistor T1 is electrically connected to a first terminal of the drive transistor T3. A second terminal of the drive transistor T3 is electrically connected to a first terminal of the first light emission control transistor T6, a second terminal of the first light emission control transistor T6 is electrically connected to a first electrode of a light-emitting device D, and a second electrode of the light-emitting device D is electrically connected to a negative power signal terminal PVEE. A control terminal of the drive transistor T3 is electrically connected to a first node A, and the drive transistor T3 is configured to control the light-emitting device D to emit light during a light emission stage. The first terminal of the data write transistor T2 is electrically connected to the data signal line data, a second terminal of the data write transistor T2 is electrically connected to the first terminal of the drive transistor T3, and a control terminal of the data write transistor T2 is electrically connected to the first scan signal line Scan1. A first terminal of the threshold compensation transistor T4 is electrically connected to the second terminal of the drive transistor T3, and a second terminal of the threshold compensation transistor T4 is electrically connected to the first node A. The data write transistor T2 is configured to write the data signal to the first node A during a data write stage. The threshold compensation transistor T4 is configured to perform threshold compensation on the drive transistor T3 during a threshold compensation stage. A first terminal of the initialization transistor T5 is electrically connected to a first reference signal terminal Vref1, a second terminal of the initialization transistor T5 is electrically connected to the control terminal of the drive transistor T3, and a control terminal of the initialization transistor T5 is electrically connected to a third scan signal line Scan3 for resetting a potential at the control terminal of the drive transistor T3. A control terminal of the reset transistor T7 is electrically connected to the third scan signal line Scan3, a first terminal of the reset transistor T7 is electrically connected to a second reference signal terminal Vref2, and a second terminal of the reset transistor T7 is electrically connected to the light-emitting device D for resetting an anode of the light-emitting device D to avoid the light emission during the previous frame affecting the light emission during the current frame.

In the embodiments, the switch element 310 also serves as the data write transistor T2, the switch signal line 330 also serves as the first scan signal line Scan1, and the switch driver circuit 320 also serves as the scan driver circuit S-VSR. Thus, the first terminal of the data write transistor T2 is further electrically connected to a second power signal line 220. In this case, the driving process of the pixel circuit 10 is shown in FIG. 6, where the working stage of the pixel circuit 10 may include an initialization stage S1, an enable stage S2 and the light emission stage S3. In the initialization stage S1, the third scan signal line Scan3 provides a low level signal, then the first initialization transistor T5 is turned on, and a gate potential of the drive transistor T3 is reset. The enable stage S2 includes a first enable stage S21 and a second enable stage S22, and the first enable stage S21 may be the data write stage. In the first enable stage S21, the first scan signal line Scan1 provides a low level signal, then the data write transistor T2 is turned on, the data signal in the data signal line data is transmitted to the first terminal of the drive transistor T3 through the data write transistor T2, and at this time, the second power signal line 220 is floating, that is, the second power signal line 220 will not write the voltage signal to the first terminal of the data write transistor T2. In the second enable stage S22, the first scan signal line Scan1 provides a low level signal, then the data write transistor T2 is turned on, the voltage signal provided by the second power signal line 220 is transmitted to the first terminal of the drive transistor T3 through the data write transistor T2, and at this time, the data signal line data is floating, that is, the data signal line data will not write the voltage signal to the first terminal of the data write transistor T2. In the light emission stage S3, a light emission control signal line Emit provides a low level signal, then the second light emission control transistor T1 and the first light emission control transistor T6 are turned on, and a drive current generated by the drive transistor T3 is transmitted to the light-emitting device D, so the light-emitting device D emits light. In this manner, in the second enable stage S22, the voltage difference caused by the voltage drop in the first power signal line 210 in the first direction X is compensated for through the second power signal line 220, so the uniformity of the voltage in the first power signal line 210 in the first direction X is improved, and the display effect of the display panel is improved. Moreover, the switch element 310 also serves as the data write transistor T2, the switch signal line 330 also serves as the first scan signal line Scan1, and the switch driver circuit 320 also serves as the scan driver circuit S-VSR, so the setting manner of the switch element 310, the switch signal line 330 and the switch driver circuit 320 is simple, the difficulty of wiring the switch element 310, the switch signal line 330 and the switch driver circuit 320 is reduced, and the overall area occupied by the circuit and the signal lines is reduced, which is conducive to leaving more space and achieving high pixels per inch (PPI) display or transparent display.

It is to be noted that the preceding embodiments illustrate the example where the transistors in the pixel circuit 10 include a P-type transistor. When a transistor is a P-type transistor, an enable signal of the transistor is a low level signal. To avoid a leakage current of the threshold compensation transistor T4 and a leakage current of the initialization transistor T5 affecting the potential stability of the first node A, the threshold compensation transistor T4 and the initialization transistor T5 may be set as double-gate transistors so that the leakage current of the threshold compensation transistor T4 and the leakage current of the initialization transistor T5 are reduced. It can be understood that the embodiments of the present application do not limit the types of the transistors. Some or all of the transistors in the pixel circuit 10 may be set as N-type transistors. For example, the threshold compensation transistor T4 and the initialization transistor T5 may not be set as N-type transistors so that the leakage current of the threshold compensation transistor T4 and the leakage current of the initialization transistor T5 are reduced.

In some embodiments, on the basis of the preceding embodiments, with continued reference to FIG. 5 and FIG. 6, the pixel circuit 10 further includes the threshold compensation transistor T4, and the display panel further includes one or more second scan signal lines Scan2 located in the display region AA. The first terminal of the threshold compensation transistor T4 is electrically connected to the second terminal of the drive transistor T3, the second terminal of the threshold compensation transistor T4 is electrically connected to the control terminal of the drive transistor T3, and a control terminal of the threshold compensation transistor T4 is electrically connected to a second scan signal line Scan2. The threshold compensation transistor T4 is configured to compensate the drive transistor T3 for a gate voltage under the control of a second scan signal provided by the second scan signal line Scan2. An enable stage of the second scan signal overlaps the first enable stage S21 in timing.

Illustratively, the first terminal of the threshold compensation transistor T4 is electrically connected to the second terminal of the drive transistor T3, the second terminal of the threshold compensation transistor T4 is electrically connected to the first node A, and the control terminal of the threshold compensation transistor T4 is electrically connected to the second scan signal line Scan2. The threshold compensation transistor T4 is configured to perform threshold compensation on the drive transistor T3 in the threshold compensation stage. It is to be understood that in the first enable stage S21, the second scan signal line Scan2 and the first scan signal line Scan1 both output turning-on signals so that the data write transistor T2 and the threshold compensation transistor T4 are simultaneously turned on. In the second enable stage S22, the first scan signal line Scan1 outputs a turning-on signal so that the data write transistor T2 also serves as the switch element 310, and the second scan signal line Scan2 outputs a turning-off signal so that the threshold compensation transistor T4 is turned off; in this manner, it is avoided that the signal of the threshold compensation transistor T4 is written to a gate of the drive transistor T3 in the second enable stage S22 and then affects a light emission current of the light-emitting device D.

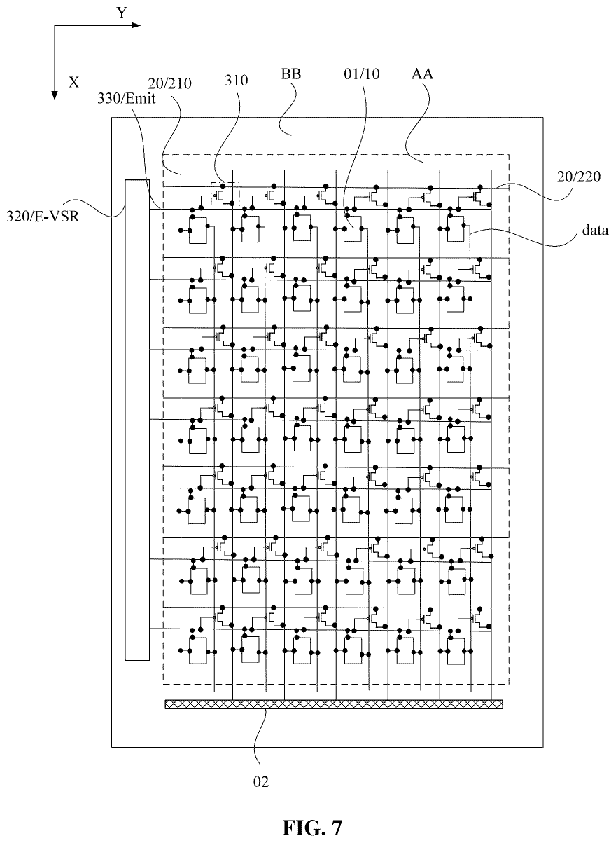

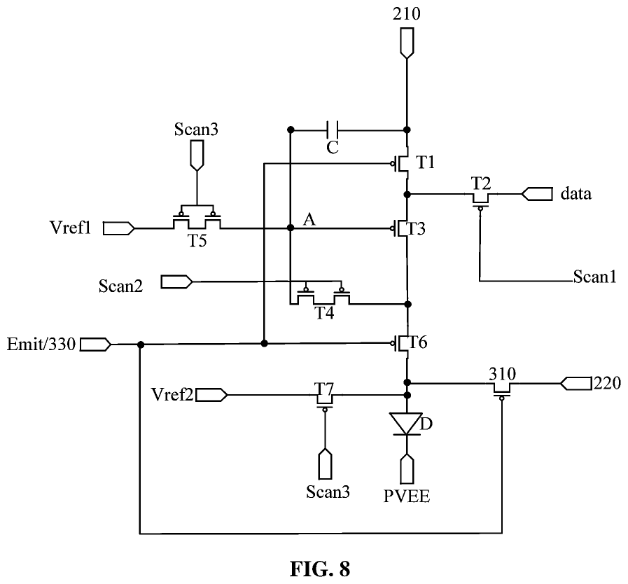

In some embodiments, FIG. 7 is a structural diagram of another display panel according to embodiments of the present application, and FIG. 8 is a structural diagram of another pixel circuit according to embodiments of the present application. Referring to FIG. 7 and FIG. 8, the pixel circuit 10 includes the first light emission control transistor T6 and the drive transistor T3. The subpixel 01 further includes the light-emitting device D. The display panel further includes one or more light emission control signal lines Emit located in the display region AA and a light emission control circuit E-VSR located in the non-display region BB. The first terminal of the first light emission control transistor T6 is electrically connected to the second terminal of the drive transistor T3, the second terminal of the first light emission control transistor T6 is electrically connected to the anode of the light-emitting device D, and a control terminal of the first light emission control transistor T6 is electrically connected to a light emission control signal line Emit. The light emission control signal line Emit is electrically connected to the light emission control circuit E-VSR for receiving a light emission control signal provided by the light emission control circuit E-VSR. The first light emission control transistor T6 is configured to output a first power signal provided by the first power signal line 210 to the anode of the light-emitting device D under the control of the light emission control signal. The second terminal of the switch element 310 is electrically connected to the second terminal of the first light emission control transistor T6.

Illustratively, in the implementation shown in FIG. 7, the shift register circuit includes the light emission control circuit E-VSR, and the light emission control circuit E-VSR may be located in the left bezel region and/or right bezel region of the display panel. The light emission control circuit E-VSR is electrically connected to the pixel circuit 10 through the light emission control signal line Emit and is configured to provide the light emission control signal for the pixel circuit 10. Moreover, a clock signal line, a high level signal line and a low level signal line may further be included between the light emission control circuit E-VSR and a driver chip located in the bottom bezel region of the display panel. The driver chip provides a clock signal, a high level signal and a low level signal for the light emission control circuit E-VSR to ensure that the light emission control circuit E-VSR can normally output the light emission control signal to the light emission control signal lines Emit.

Referring to FIG. 8, the pixel circuit 10 further includes the first light emission control transistor T6 and the drive transistor T3. The second terminal of the drive transistor T3 is electrically connected to the first terminal of the first light emission control transistor T6, the second terminal of the first light emission control transistor T6 is electrically connected to the anode of the light-emitting device D, and a cathode of the light-emitting device D is electrically connected to the negative power signal terminal PVEE. In the light emission stage, the light emission control signal line Emit provides a low level signal, then the first light emission control transistor T6 is turned on, and the drive current generated by the drive transistor T3 is transmitted to the light-emitting device D, so the light-emitting device emits light. In the embodiments of the present application, the first terminal of the switch element 310 is electrically connected to the second power signal line 220, and the second terminal of the switch element 310 is electrically connected to the second terminal of the first light emission control transistor T6. In this manner, in the light emission stage, the switch element 310 is turned on so that the voltage in the second power signal line 220 serves as the compensation to the first power signal line 210, so the voltage difference caused by the voltage drop in the first power signal line 210 in the first direction X is reduced, the uniformity of the voltage in the first power signal line 210 is improved, and the display effect of the display panel is enhanced. Moreover, in the embodiments of the present application, the switch element 310 is independent of the pixel circuit in the related art, so it is not necessary to change the structure and working timing of the related pixel circuit, and the working state of the pixel circuit will not be affected and the display effect is ensured while the compensation for the first power signal line 210 is achieved.

In some embodiments, in the implementation shown in FIG. 8, the switch signal line 330 also serves as the light emission control signal line Emit, and the switch driver circuit 320 also serves as the light emission control circuit E-VSR. In this manner, the difficulty of wiring the switch signal lines 330 can be reduced, the overall area occupied by signal lines can be reduced, which is conducive to leaving more space and achieving high PPI display or transparent display.

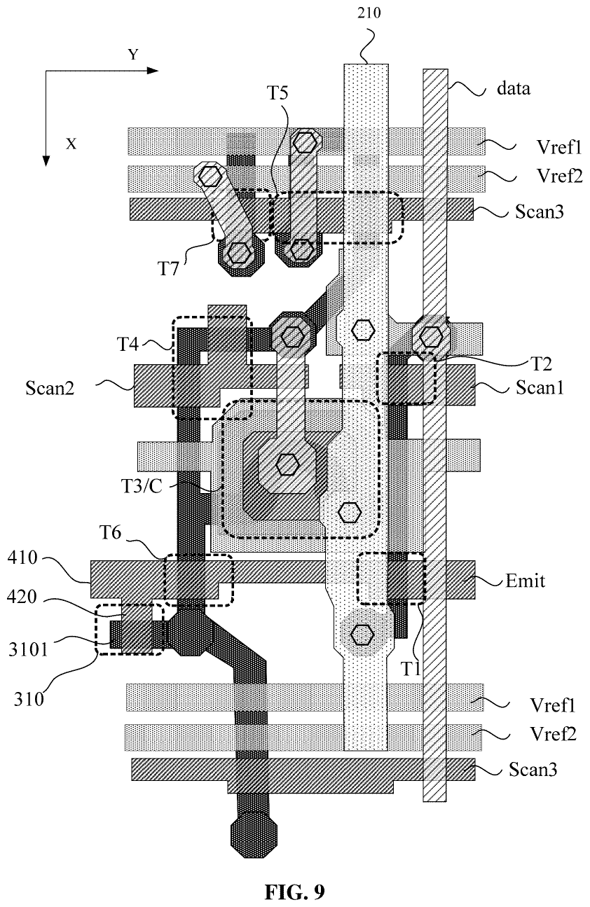

In some embodiments, FIG. 9 is a structural diagram illustrating the layout of a pixel circuit according to embodiments of the present application. As shown in FIG. 9, an active portion 3101 of the switch element 310 is electrically connected to an active portion of the first light emission control transistor T6. Illustratively, the active portion 3101 of the switch element 310 is the part of an active layer corresponding to the switch element 310, and the active portion of the first light emission control transistor T6 is the part of the active layer corresponding to the first light emission control transistor T6. The active portion 3101 of the switch element 310 is electrically connected to the active portion of the first light emission control transistor T6, so it is ensured that the switch element 310 is disposed between the first light emission control transistor T6 and the light-emitting device. Moreover, the setting position of the switch element 310 may be combined with the related pixel circuit to ensure that the newly added switch element 310 does not occupy too much area, which is conducive to leaving more space and achieving high PPI display or transparent display.

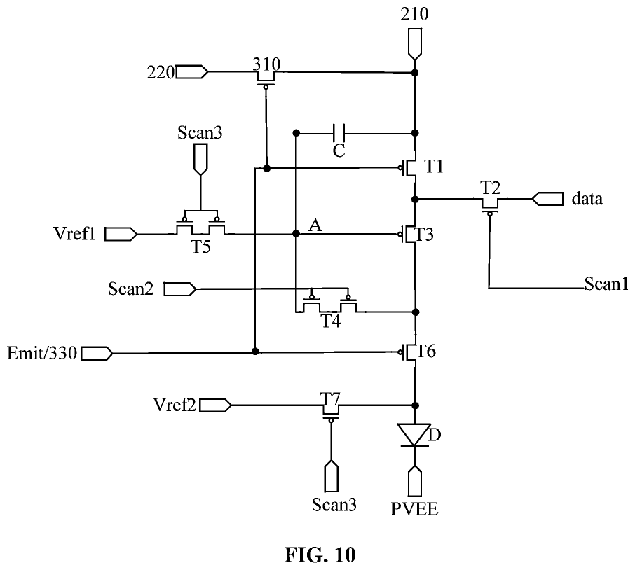

In some embodiments, FIG. 10 is a structural diagram of another pixel circuit according to embodiments of the present application. Referring to FIG. 10, the pixel circuit 10 includes the second light emission control transistor T1 and the drive transistor T3. The display panel further includes one or more light emission control signal lines Emit located in the display region AA and the light emission control circuit E-VSR located in the non-display region BB. The first terminal of the second light emission control transistor T1 is electrically connected to a first power signal line 210, the second terminal of the second light emission control transistor T1 is electrically connected to the first terminal of the drive transistor T3, and a control terminal of the second light emission control transistor T1 is electrically connected to a light emission control signal line Emit. The light emission control signal line Emit is electrically connected to the light emission control circuit E-VSR for receiving the light emission control signal provided by the light emission control circuit E-VSR. The second light emission control transistor T1 is configured to output the first power signal provided by the first power signal line 210 to the first terminal of the drive transistor T3 under the control of the light emission control signal. The second terminal of the switch element 310 is electrically connected to the first terminal of the second light emission control transistor T1.

Referring to FIG. 10, in the embodiments of the present application, the switch element 310 may also be disposed between the first power signal line 210 and the second light emission control transistor T1. In the light emission stage, the light emission control signal line Emit outputs a turning-on signal to the control terminal of the switch element 310 so that the switch element 310 is turned on, and thus through the switch element 310, the voltage in the second power signal line 220 serves as the compensation to the first power signal line 210, so the voltage difference caused by the voltage drop in the first power signal line 210 in the first direction X is reduced, the uniformity of the voltage in the first power signal line 210 is improved, and the display effect of the display panel is enhanced. Moreover, in the embodiments of the present application, the switch element 310 is independent of the pixel circuit in the related art, so it is not necessary to change the structure and working timing of the related pixel circuit, and the working state of the pixel circuit will not be affected and the display effect is ensured while the compensation for the first power signal line 210 is achieved.

It is to be noted that the switch element 310 will generate a leakage current during working. In the embodiments of the present application, the switch element 310 is disposed between the first power signal line 210 and the second light emission control transistor T1, that is, the second light emission control transistor T1, the drive transistor T3 and the first light emission control transistor T6 are further included between the switch element 310 and the light-emitting device D, so the leakage current control can be controlled through multiple transistors between the switch element 310 and the light-emitting device D. Compared with the scheme where the switch element 310 is disposed between the first light emission control transistor T6 and the light-emitting element D, this scheme can further improve the compensation effect performed by the second power signal line 220 on the first power signal line 210.

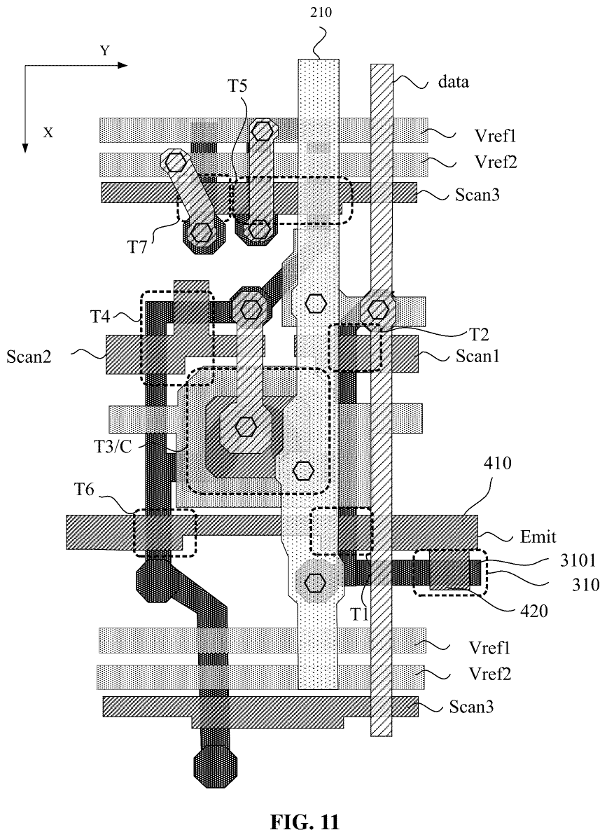

In some embodiments, FIG. 11 is a structural diagram illustrating the layout of a pixel circuit according to embodiments of the present application. As shown in FIG. 11, the active portion 3101 of the switch element 310 is electrically connected to an active portion of the second light emission control transistor T1. Illustratively, the active portion 3101 of the switch element 310 is the part of the active layer corresponding to the switch element 310, and the active portion of the second light emission control transistor T1 is the part of the active layer corresponding to the second light emission control transistor T1. The active portion 3101 of the switch element 310 is electrically connected to the active portion of the second light emission control transistor T1, so it is ensured that the switch element 310 is disposed between the second light emission control transistor T1 and the first power signal line 210. Moreover, the setting position of the switch element 310 may be combined with the related pixel circuit to ensure that the newly added switch element 310 does not occupy too much area, which is conducive to leaving more space and achieving high PPI display or transparent display.

In some embodiments, on the basis of the preceding embodiments, with continued reference to FIG. 8 and FIG. 10, the switch signal line 330 also serves as the light emission control signal line Emit, and the switch driver circuit 320 also serves as the light emission control circuit E-VSR. In this manner, the setting manner of the switch signal line 330 and the switch driver circuit 320 is simple, the difficulty of wiring the switch signal line 330 and the switch driver circuit 320 is reduced, and the overall area occupied by the circuit and the signal lines is reduced, which is conducive to leaving more space and achieving high PPI display or transparent display.

In some embodiments, on the basis of the preceding embodiments, with continued reference to FIG. 9, the light emission control signal line Emit includes a main body portion 410 and an extension portion 420 which are connected, at least part of the main body portion 410 extends in the second direction Y, and at least part of the extension portion 420 extends in the first direction X. The extension portion 420 overlaps the active portion 3101 of the switch element 310 as the control terminal of the switch element 310.

Illustratively, at least part of the main body portion 410 extends in the second direction Y and overlaps the active portion of the first light emission control transistor T6 and the active portion of the second light emission control transistor T1 to serve as the control terminal of the first light emission control transistor T6 and the control terminal of the second light emission control transistor T1 respectively, so as to provide the light emission control signal for the first light emission control transistor T6 and the second light emission control transistor T1. At least part of the extension portion 420 extends in the first direction X, and the extension portion 420 overlaps the active portion 3101 of the switch element 310 as the control terminal of the switch element 310 to provide the light emission control signal for the switch element 310, so through the switch element 310, the voltage in the second power signal line 220 serves as the compensation to the first power signal line 210 during the light emission stage; in this manner, while the compensation for the first power signal line 210 is achieved, the switch signal line 330 also serves as the light emission control signal line Emit, so the difficulty of wiring the switch signal line 330 is reduced.

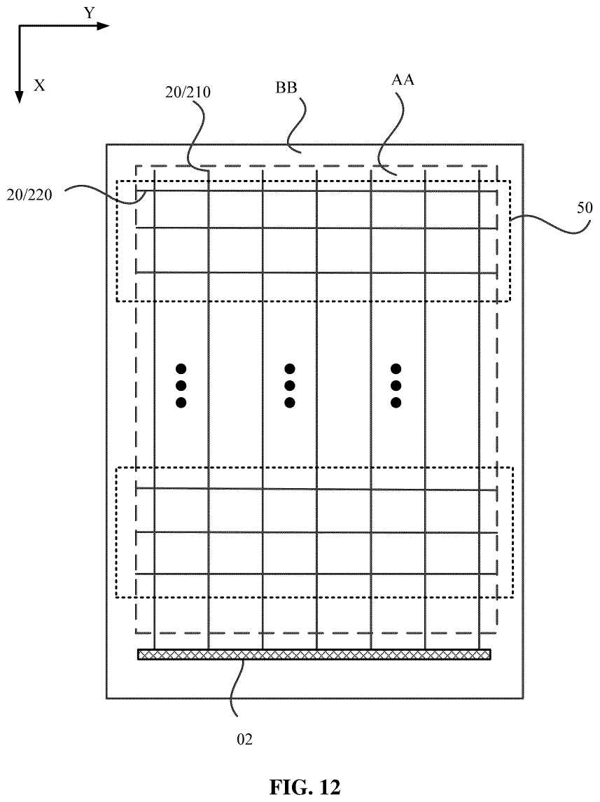

In some embodiments, FIG. 12 is a structural diagram of another display panel according to embodiments of the present application. Referring to FIG. 12, the display panel includes multiple signal line groups 50, and each signal line group 50 includes at least one second power signal line. In the same signal line group 50, a power signal in the at least one second power signal line 220 has the same voltage. Among at least two signal line groups, a voltage of a power signal in a second power signal line 220 in a signal line group 50 facing the first power bus line 02 is smaller than a voltage of a power signal in a second power signal line 220 in a signal line group 50 facing away from the first power bus line 02.

Illustratively, the display panel may include multiple signal line groups 50, and each signal line group 50 includes at least one second power signal line 220. FIG. 12 exemplarily illustrates, but does not limit, the example where each signal line group 50 includes three second power signal lines 220. In other embodiments, each signal line group 50 may also include another number of power signal lines 220. In the same signal line group 50, power signals in second power signal lines 220 have the same voltage, that is, the second power signal lines 220 in the same signal line group 50 may be connected to the same fixed potential so that positions on the first power signal line 210 corresponding to the same signal line group 50 are compensated by the same voltage. In other words, the compensation may be performed on the first power signal line 210 in units of signal line groups 50. Little difference exists between compensation signals in two adjacent second power signal lines 220, so second power signal lines 220 in the same signal line group 50 may be connected to the same fixed potential so that the positions on the first power signal line 210 corresponding to the same signal line group 50 are compensated by the same voltage. In this manner, on the basis of achieving the compensation for the power signals in the first power signal lines 210, the compensation method can be simplified. For example, the connection manner between second power signal lines 220 and fixed potential signal terminals can be simplified, and the number of fixed potential signal terminals can be reduced, which ensures that the scheme of the compensation for the first power signal line 210 is simple and feasible.

Moreover, when the first power bus line 02 provides positive power signals for the pixel circuits 10 through the first power signal lines 210, the voltage of the side of the first power signal line 210 facing the first power bus line 02 is larger than the voltage of the side of the first power signal line 210 facing away from the first power bus line 02. Then, it is set that among at least two signal line groups, the voltage of the power signal in the second power signal line 220 in the signal line group 50 facing the first power bus line 02 is smaller than the voltage of the power signal in the second power signal line 220 in the signal line group 50 facing away from the first power bus line 02. In this manner, the smaller voltage in the second power signal line 220 in the signal line group 50 facing the first power bus line 02 compensates for the side of the first power signal line 210 having larger voltage and facing the first power bus line 02, and the larger voltage in the second power signal line 220 in the signal line group 50 facing away from the first power bus line 02 compensates for the side of the first power signal lines 210 having smaller voltage and facing away from the first power bus line 02, so the voltage difference is reduced between the side of the first power signal line 210 facing the first power bus line 02 and the side of the first power signal line 210 facing away from the first power bus line 02, thus the uniformity of the voltage in the first power signal line 210 in the first direction X is improved, and the display effect of the display panel is improved.

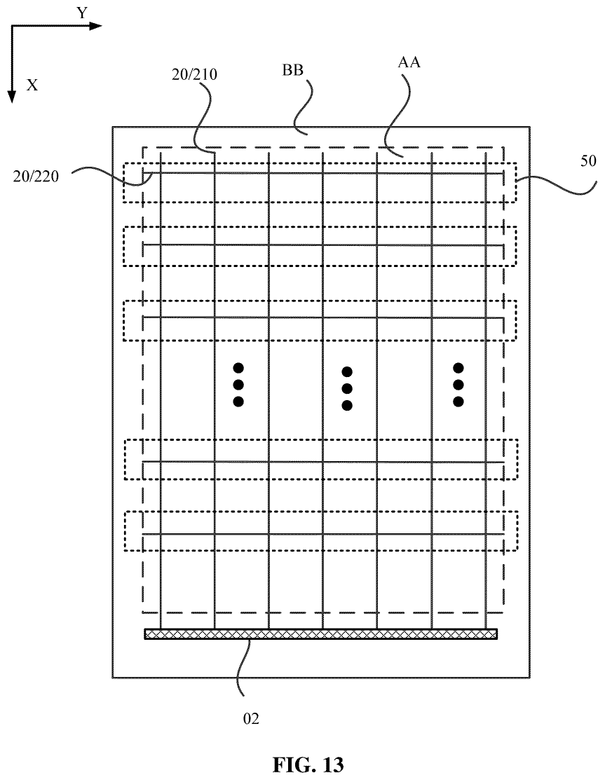

In some embodiments, FIG. 13 is a structural diagram of another display panel according to embodiments of the present application. Referring to FIG. 13, each signal line group 50 includes one second power signal line 220. Illustratively, as shown in FIG. 13, each signal line group 50 includes one second power signal line 220, that is, when the voltage compensation is performed on the first power signal lines 210 through the second power signal lines 220, the compensation is performed in units of one second power signal line 220. In this manner, the voltage compensation is performed on more positions on the first power signal line 210 in the first direction X, in other words, the division of compensation positions on the first power signal line 210 in the first direction X is finer, which can achieve precise compensation.

In some embodiments, on the basis of the preceding embodiments, with continued reference to FIG. 12, each signal line group 50 includes at least two second power signal lines 220. Exemplarily, in the implementation shown in FIG. 12, each signal line group 50 includes three second power signal lines 220. Thus, when the voltage compensation is performed on the first power signal line 210, through the multiple second power signal lines 220 in the same signal line group 50, the positions on the first power signal lines 210 corresponding to the same signal line group 50 may be simultaneously compensated with the same voltage. In this manner, the compensation manner can be simplified, for example, the connection manner between second power signal lines 220 and the fixed potential signal terminals can be simplified, and the number of fixed potential signal terminals can be reduced, which ensures that the compensation manner is simple and efficient.

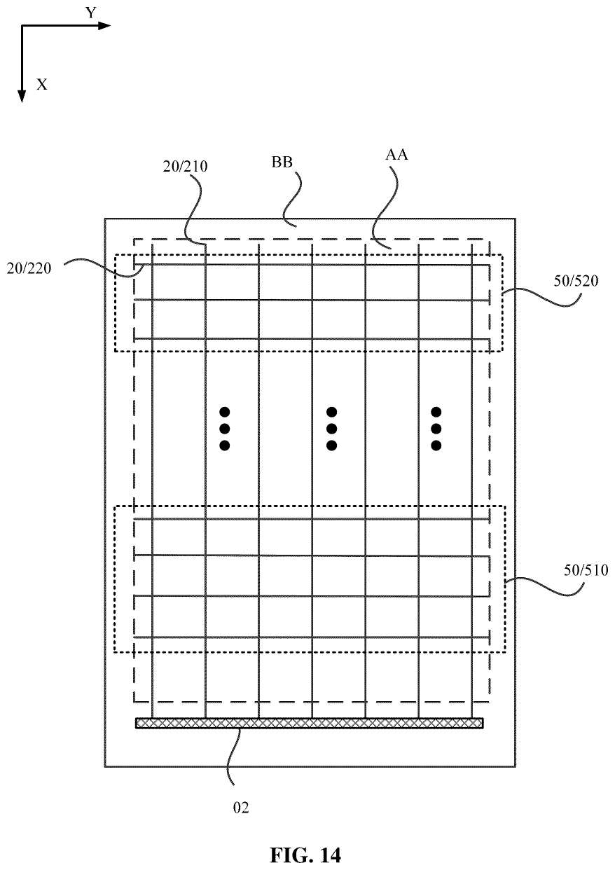

In some embodiments, FIG. 14 is a structural diagram of another display panel according to embodiments of the present application. Referring to FIG. 14, the at least two signal line groups 50 include a first signal line group 510 and a second signal line group 520. The first signal line group 510 is located on a side of the second signal line group 520 facing the first power bus line 02. The number of second power signal lines 220 in the first signal line group 510 is larger than the number of second power signal lines 220 in the second signal line group 520.

Illustratively, the impact caused by the voltage drop varies at different positions on the first power signal line 210. Exemplarily, positions on the first signal line 210 facing the first power bus line 02 are less affected by the voltage drop, that is, the closer the positions on the first power signal line 210 to the first power bus line 02, the smaller the decrease in the voltage; while positions on the first power signal line 210 facing away from the first power bus line 02 are more affected by the voltage drop, that is, the farther the positions on the first power signal line 210 to the first power bus line 02, the greater the decrease in the voltage. Thus, in the embodiments of the present application, the number of second power signal lines 220 in the first signal line group 510 facing the first power bus line 02 is larger than the number of second power signal lines 220 in the second signal line group 520 facing away from the first power bus line 02. That is, a larger number of second power signal lines 220 are disposed at the positions on the first power signal lines 210 which are less affected by the voltage drop, and the second power signal lines 220 provide a smaller compensation voltage. In this manner, the compensation manner can be simplified, for example, the connection manner between second power signal lines 220 and the fixed potential signal terminals can be simplified, and the number of fixed potential signal terminals can be reduced, which ensures that the compensation manner is simple and efficient. A smaller number of second power signal lines 220 are disposed at the positions on the first power signal lines 210 which are more affected by the voltage drop, and the second power signal lines 220 provide a larger compensation voltage. In this manner, relatively accurate compensation can be performed on the first power signal lines 210 facing away from a side of the first power bus line 02, which ensures the good compensation effect on the first power signal lines 210. Therefore, the number of second power signal lines 220 included in each power signal line group 50 and/or the voltage in second power signal lines 220 included in each power signal line group 50 may be set differently. Through the different setting of the number and/or the voltage, the accuracy of the compensation can be improved while the compensation manner is simplified, that is, the accuracy of the compensation and the control logic are balanced.

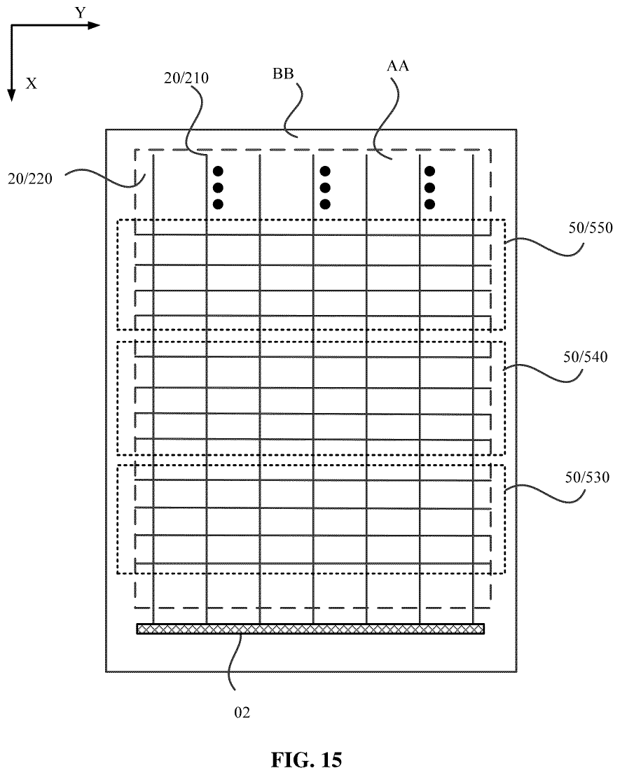

In some embodiments, in an implementation, FIG. 15 is a structural diagram of another display panel according to embodiments of the present application. Referring to FIG. 15, the multiple signal line groups 50 include a third signal line group 530, a fourth signal line group 540 and a fifth signal line group 550, and the third signal line group 530, the fourth signal line group 540 and the fifth signal line group 550 are disposed adjacent to one another in the first direction X. The third signal line group 530 is located on a side of the fourth signal line group 540 facing the first power bus line 02, and the fourth signal line group 540 is located on a side of the fifth signal line group 550 facing the first power bus line 02. A first difference exists between a voltage of a power signal in a second power signal line 220 in the fourth signal line group 540 and a voltage of a power signal in a second power signal line 220 in the third signal line group 530. A second difference exists between a voltage of a power signal in a second power signal line 220 in the fifth signal line group 550 and the voltage of the power signal in the second power signal line 220 in the fourth signal line group 540. The first difference is equal to the second difference.

Illustratively, in the implementation shown in FIG. 15, the third signal line group 530, the fourth signal line group 540 and the fifth signal line group 550 are arranged in sequence in the first direction X, and the third signal line group 50 is located at a position closest to the first power bus line 02. Then, it is set that the first difference between the voltage of the power signal in the second power signal line 220 in the fourth signal line group 540 and the voltage of the power signal in the second power signal line 220 in the third signal line group 530 is equal to the second difference between the voltage of the power signal in the second power signal line 220 in the fifth signal line group 550 and the voltage of the power signal in the second power signal line 220 in the fourth signal line group 540, so the voltage of the power signal in the second power signal line 220 in the third signal line group 530, the voltage of the power signal in the second power signal line 220 in the fourth signal line group 540 and the voltage of the power signal in the second power signal line 220 in the fifth signal line group 550 form an arithmetic progression to further match the gradually increasing voltage drop in a first power signal line 210 in the first direction X. In this manner, the accuracy of the compensation on the first power signal line 210 is further improved while the compensation logic is simplified.

In other embodiments, with continued reference to FIG. 15, the multiple signal line groups 50 include a third signal line group 530, a fourth signal line group 540 and a fifth signal line group 550, and the third signal line group 530, the fourth signal line group 540 and the fifth signal line group 550 are disposed adjacent to one another in the first direction X. The third signal line group 530 is located on a side of the fourth signal line group 540 facing the first power bus line 02, and the fourth signal line group 540 is located on a side of the fifth signal line group 550 facing the first power bus line 02. A first difference exists between a voltage of a power signal in a second power signal line 220 in the fourth signal line group 540 and a voltage of a power signal in a second power signal line 220 in the third signal line group 530. A second difference exists between a voltage of a power signal in a second power signal line 220 in the fifth signal line group 550 and the voltage of the power signal in the second power signal line 220 in the fourth signal line group 540. The first difference is less than the second difference.

Illustratively, the voltage drop at different positions on the first power signal line 210 varies nonlinearly, that is, the closer the positions on the first power signal line 210 to the first power bus line 02, the smaller the change in the voltage drop, and the smaller the change in the compensation voltage; the farther the positions on the first power signal line 210 to the first power bus line 02, the larger the change in the voltage drop, and the larger the change in the compensation voltage. Thus, the first difference between the voltage of the power signal in the second power signal line 220 in the fourth signal line group 540 and the voltage of the power signal in the second power signal line 220 in the third signal line group 530 is set to be less than the second difference between the voltage of the power signal in the second power signal line 220 in the fifth signal line group 550 and the voltage of the power signal in the second power signal line 220 in the fourth signal line group 540 to match the change in the voltage drop in the first power signal line 210 in the first direction X, or to match the change in the compensation voltage for the first power signal line 210 in the first direction X. In this manner, the accuracy of the compensation for the first power signal lines 210 can be further improved.

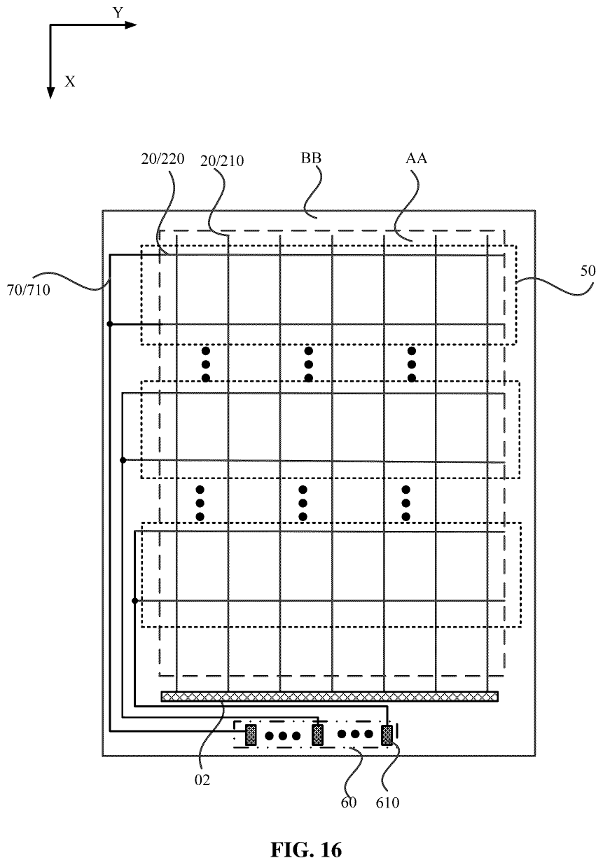

In some embodiments, FIG. 16 is a structural diagram of another display panel according to embodiments of the present application. Referring to FIG. 16, the display panel further includes a power signal terminal group 60 located in the non-display region BB. The signal line groups 50 are electrically connected to the power signal terminal group 60 correspondingly. Exemplarily, in the implementation shown in FIG. 16, the power signal terminal group 60 may be located in the bottom bezel region of the display panel. The power signal terminal group 60 is electrically connected to the signal line groups 50 located in the display panel correspondingly, so power signals are provided for the signal line groups 50 through the power signal terminal group 60, which ensures that second power signal lines 220 in the signal line groups 50 can transmit fixed signals. It is to be understood that the power signals transmitted in the power signal terminal group 60 are different from the power signals transmitted in the first power bus line 02, ensuring that when first power signal lines 210 are electrically connected to second power signal lines 220 indirectly, the voltages in the second power signal lines 220 can serve as the compensation to the voltage in the first power signal lines 210.

Further, as shown in FIG. 16, the display panel may further include a driver circuit. The driver chip includes the preceding power signal terminal group 60, and power signals are provided for the power signal terminal group 60 through the driver chip, ensuring that the signal line groups 50 receive the power signals normally. Alternatively, the display panel may further include a flexible circuit board, and the power signal terminal group 60 may be disposed on the flexible circuit board, so power signals are provided for the power signal terminal group 60 through the flexible circuit board.

In some embodiments, on the basis of the preceding embodiments, with continued reference to FIG. 16, the power signal terminal group 60 includes multiple power signal terminals 610, and power signals transmitted in different power signal terminals 610 have different voltages. Signal line groups 50 having different voltages are electrically connected to different power signal terminals 610.

Exemplarily, in the implementation shown in FIG. 16, the power signal terminal group 60 includes multiple power signal terminals 610. The display region AA includes multiple signal line groups 50, and power signals transmitted in second power signal lines 220 in the same signal line group 50 have the same voltage. Thus, it may be set that the number of power signal terminals 610 is equal to the number of signal line groups 50, and the power signal terminals 610 are set to be in one-to-one correspondence with the signal line groups 50. In this manner, signal line groups 50 having different voltages are electrically connected to different power signal terminals 610 and thus can directly control different power signal terminals to output different power signals, so power signals transmitted in second power signal lines 220 in different signal line groups 50 have different voltages, ensuring that the control logic of the driver chip is simple. Moreover, the same power signal terminal 610 corresponds to multiple second power signal lines 220, so the number of power signal terminals 610 can be reduced, ensuring the structure of the driver chip or the structure of the flexible circuit board to be simple.

It is to be noted that when a signal line group 50 includes multiple second power signal lines 220, the power signal terminals 610 and the signal line groups 50 may be connected through buses. Exemplarily, in the implementation shown in FIG. 16, the display panel further includes a second power signal bus line group 70 located in the non-display region BB. The second power signal bus line group 70 includes at least two second power signal buses 710. Each second power signal bus 710 is electrically connected to multiple second power signal lines 220 in the same corresponding signal line group 50, and each second power signal bus 710 is electrically connected to a corresponding power signal terminal 610. Thus, the power signal terminal 610 provides power signals having the same voltage for the second power signal lines 220 in the corresponding signal line group 50 through the corresponding second power signal bus 710, ensuring the simple transmission manner of the power signals.

It is to be understood that FIG. 16 only illustrates, but does not limit, the example where at least two second power bus lines 710 extend in the first direction and are arranged in the second direction Y, that is, the second power signal bus line group 70 is located in the left bezel region and/or right bezel region of the display panel. In other implementations, at least two second power bus lines 710 may also extend in the second direction Y and are arranged in the first direction X, that is, the second power signal bus line group 70 may also be located in the top bezel region and/or bottom bezel region of the display panel, which may be set by those skilled in the art as needed.

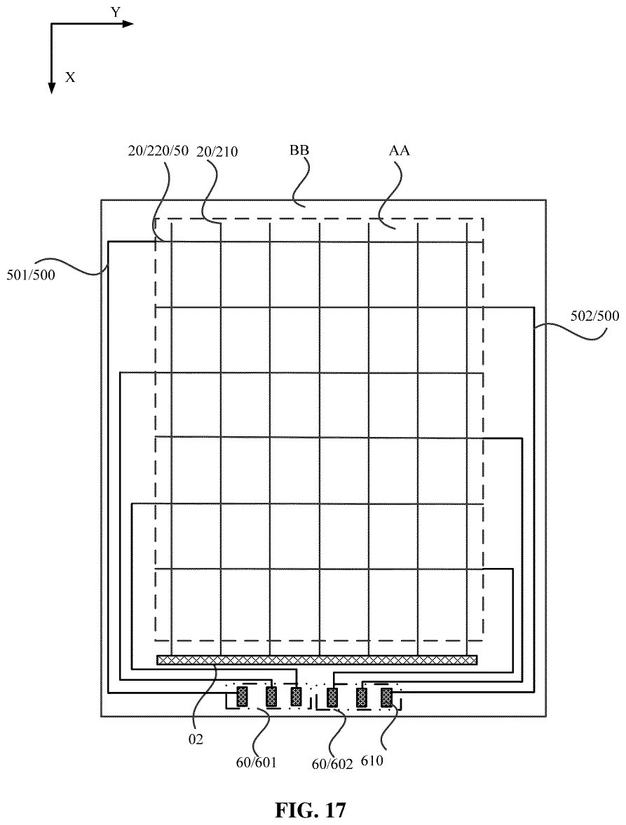

In another embodiment, FIG. 17 is a structural diagram of another display panel according to embodiments of the present application. Referring to FIG. 17, the power signal terminal group 60 includes a first power signal terminal group 601 and a second power signal terminal group 602. In the second direction Y, the first power signal terminal group 601 and the second power signal terminal group 602 are located on two opposite sides and are located in the display region AA respectively. Exemplarily, the power signal terminal group 60 is located in the bottom bezel region of the display panel. Thus, the first power signal terminal group 601 may be disposed at a position in the bottom bezel region facing the left bezel region, and the second power signal terminal group 602 may be disposed at a position in the bottom bezel region facing the right bezel region. The display panel further includes connection wires 500 located in the non-display region BB. The connection wires 500 include first connection wires 501 and second connection wires 502. In the second direction Y, the first connection wires 501 and the second connection wires 502 are located on two opposite sides of the display panel respectively. Exemplarily, the first connection wires 501 may be located in the left bezel region of the display panel, and then the first connection wires 501 may be electrically connected to signal line groups 50 in the display region AA and the first power signal terminal group 601 located on a side of the bottom bezel region facing the left bezel region. The second connection wires 502 may be located in the right bezel region of the display panel, and then the second connection wires 502 may be electrically connected to signal line groups 50 in the display region AA and the second power signal terminal group 602 located on a side of the bottom bezel region facing the right bezel region. In this manner, the first connection wires 501 located in the left bezel region are connected to the first power signal terminal group 601, and the second connection wires 502 located in the right bezel region are connected to the second power signal terminal group 602. Through this double-sided wiring setting, the difficulty of wiring the connection wires 500 can be reduced, avoiding the situation in which more connection wires 500 arranged on one side of the display panel results in a relatively wide bezel on this side, and facilitating the realization of a narrow bezel.

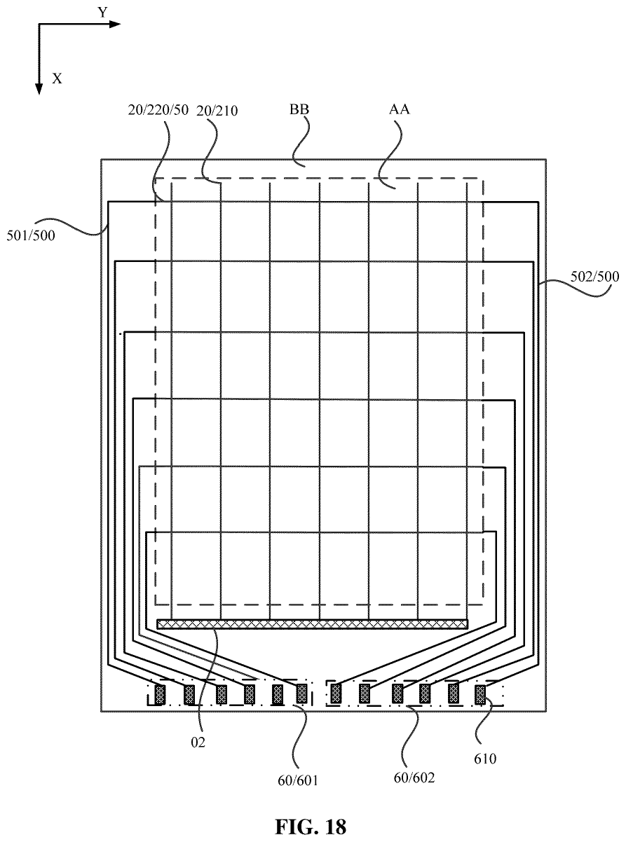

It is to be noted that the first connection wires 501 may connect some signal line groups 50 and the first power signal terminal group 601, while the second connection wires 502 may connect the other signal line groups 50 and the second power signal terminal group 602. Exemplarily, in the implementation shown in FIG. 17, the first connection wires 501 may connect to odd-numbered rows of signal line groups 50, and the second connection wires 502 may connect to even-numbered rows of signal line groups 50, which is not limited in the embodiments of the present application. In other implementations, the first connection wires 501 may connect to signal line groups 50 located in the upper half of the display region AA, and the second connection wires 502 may connect to signal line groups 50 located in the lower half of the display region AA. Moreover, in other embodiments, FIG. 18 is a structural diagram of another display panel according to embodiments of the present application. Referring to FIG. 18, the same signal line group 50 is electrically connected to the first power signal terminal group 601 through a first connection wire 501 and is electrically connected to the second power signal terminal group 602 through a second connection wire 502. That is, the same signal line group 50 can simultaneously provide power signals through the first power signal terminal group 601 located on the side of the bottom bezel region facing the left bezel region and the second power signal terminal group 602 located on the side of the bottom bezel region facing the right bezel region. In this manner, the loss of power signals during horizontal transmission can be reduced, and the compensation effect of the second power signal lines 220 can be improved.

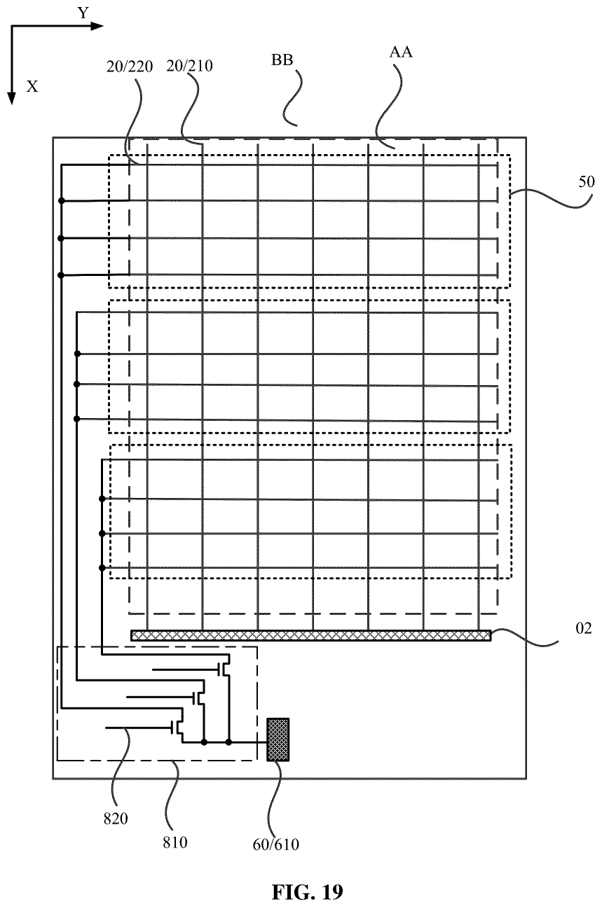

In some embodiments, FIG. 19 is a structural diagram of another display panel according to embodiments of the present application. Referring to FIG. 19, the power signal terminal group 60 includes at least one power signal terminal 610, and the number of the at least one power signal terminal 610 is smaller than the number of the signal line groups 50. At least two signal line groups 50 are electrically connected to the same power signal terminal 610, and are configured to receive power signals in a time division manner, where the power signals have different voltages and are transmitted by the same power signal terminal 610.

Exemplarily, in the implementation shown in FIG. 19, the example where the power signal terminal group 60 includes one power signal terminal 610 is illustrated. Illustratively, in the embodiment, one power signal terminal 610 is electrically connected to multiple signal line groups 50 simultaneously. Signals are transmitted in the time division manner. For example, when the display panel includes three signal line groups 50, in a first transmission stage, the power signal terminal 610 transmits a power signal having a first voltage to the first signal line group 50; in a second transmission stage, the power signal terminal 610 transmits a power signal having a second voltage to the second signal line group 50; and in a third transmission stage, the power signal terminal 610 transmits a power signal having a third voltage to the third signal line group 50. The first voltage, the second voltage and the third voltage are different from one another, and the period of the first transmission stage, the period of the second transmission stage and the period of the third transmission stage are different from one another. In this manner, different signal line groups 50 can receive power signals having different voltages transmitted by the power signal terminal 610 in the time division manner. Moreover, the same power signal terminal 610 corresponds to multiple signal line groups 50, so compared with the scheme where one first power signal terminal 610 corresponds to one signal line group 50, the number of power signal terminals 610 can be further reduced, and thus the setting manner of the power signal terminals 610 can be simplified.

It is to be noted that FIG. 19 only exemplarily illustrates the example where the power signal terminal group 60 includes one power signal terminal 610. In other embodiments, the power signal terminal group 60 may also include multiple power signal terminals 610, and the same power signal terminal 610 is electrically connected to multiple signal line groups 50.

On the basis of the preceding embodiments, with continued reference to FIG. 19, the display panel further includes a de-multiplexing circuit 810 located in the non-display region BB and de-multiplexing signal lines 820 located in the non-display region BB. An input terminal of the de-multiplexing circuit 810 is electrically connected to a power signal terminal 610, output terminals of the de-multiplexing circuit 810 are electrically connected to the signal line groups 50, and control terminals of the de-multiplexing circuit 810 are electrically connected to the de-multiplexing signal lines 820. The de-multiplexing circuit 810 is configured to transmit a power signal transmitted by the power signal terminal 610 to different signal line groups 50 in the time division manner under the control of a de-multiplexing control signal provided by the de-multiplexing signal lines 820, and the input terminal number of the de-multiplexing circuit 810 is smaller than the number of the output terminals of the de-multiplexing circuit 810.

In the implementation shown in FIG. 19, the de-multiplexing circuit 810 includes multiple transistors, and input terminals of the multiple transistors are all electrically connected to the power signal terminal 610 so that the input terminal of the de-multiplexing circuit 810 is electrically connected to the power signal terminal 610. Output terminals of the multiple transistors are electrically connected to corresponding signal line groups 50 respectively so that the output terminals of the de-multiplexing circuit 810 are electrically connected to the corresponding signal line groups 50. The number of de-multiplexing signal lines 820 is equal to the number of transistors included in the de-multiplexing circuit 81, and control terminals of the transistors are set in one-to-one correspondence with the de-multiplexing signal lines 820, so the control terminals of the de-multiplexing circuit 810 are electrically connected to the de-multiplexing signal lines 820. When signals are transmitted, the power signal terminal 610 transmits power signals through the de-multiplexing circuit 810 in the time division manner. Exemplarily, the example where the display region includes three signal line groups 50, and the three signal line groups 50 are connected to the same power signal terminal 610 is illustrated. In a first transmission stage, a first de-multiplexing signal line outputs a turning-on signal, and a second de-multiplexing signal line and a third de-multiplexing signal line both output turning-off signals, so a transistor corresponding to the first signal line group 50 is turned on, and the power signal terminal 610 outputs a first voltage to the first signal line group 50. In a second transmission stage, the second de-multiplexing signal line outputs a turning-on signal, and the first de-multiplexing signal line and the third de-multiplexing signal line both output turning-off signals, so a transistor corresponding to the second signal line group 50 is turned on, and the power signal terminal 610 outputs a second voltage to the second signal line group 50. In a third transmission stage, the third de-multiplexing signal line outputs a turning-on signal, and the second de-multiplexing signal line and the first de-multiplexing signal line both output turning-off signals, so a transistor corresponding to the third signal line group 50 is turned on, and the power signal terminal 610 outputs a third voltage to the third signal line group 50. In this manner, the de-multiplexing circuit 810 transmits power signals transmitted by the power signal terminal 610 to different signal line groups 50 in the time division manner under the effect of the de-multiplexing control signal provided by the de-multiplexing signal lines 820, so through different signal line groups 50, power signals having different voltages serve as the compensation for different positions on the first power signal lines 210.

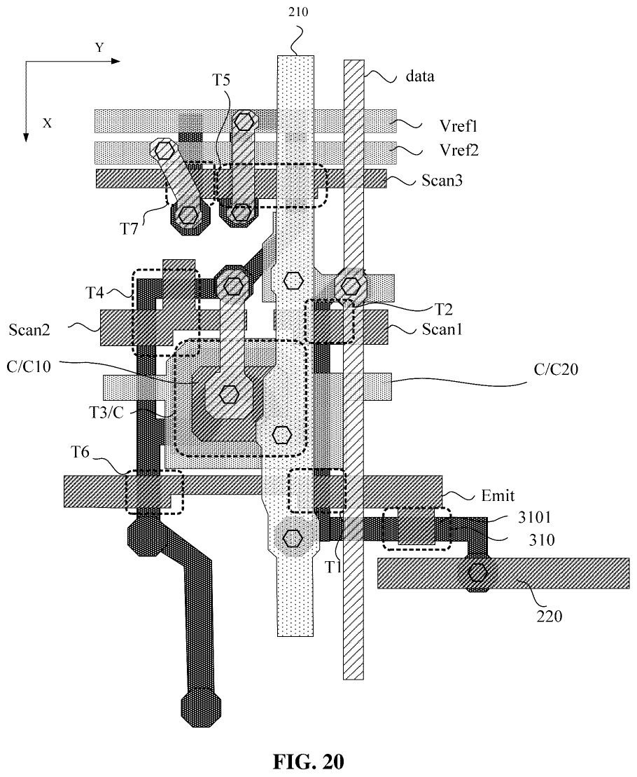

In some embodiments, FIG. 20 is a structural diagram illustrating the layout of another pixel circuit according to embodiments of the present application. Referring to FIG. 20, the pixel circuit includes a storage capacitor C, and the storage capacitor C includes a first capacitor plate C10 and a second capacitor plate C20 which are disposed opposite to each other. The display panel further includes a substrate, and the second capacitor plate C20 is located on a side of the first capacitor plate C10 facing away from the substrate. The second power signal lines 220 are disposed in the same layer as the first capacitor plate C10 and/or the second capacitor plate C20.

Illustratively, in the implementation shown in FIG. 20, the first capacitor plate C10 of the capacitor C is located in a first metal layer (MI), and the second capacitor plate of the capacitor C is located in a second metal layer (MC). The newly added second power signal lines 220 are located in the first metal layer and/or second metal layer, so the second power signal lines 220 can be disposed in the same layer as an original structure in the related pixel circuit without the addition of a new film layer, and thus the thickness of the display panel is not increased, which is conducive to the thinning development of the display panel.

In some embodiments, on the basis of the preceding embodiments, with continued reference to FIG. 1 and FIG. 5, the subpixel 01 further includes the light-emitting device D. The light-emitting device D includes a micro light-emitting diode (LED). Illustratively, micro light-emitting diodes involve a high miniaturized LED technology. Through this technology, conventional LEDs are arrayed and miniaturized and then transferred to a circuit board through addressing to form LEDs having ultra-small spacing, so ultra-high pixel density and ultra-high resolution can be achieved. Moreover, micro light-emitting diodes may be bonded onto a transparent substrate, which is conducive to the transparent display of the display panel.

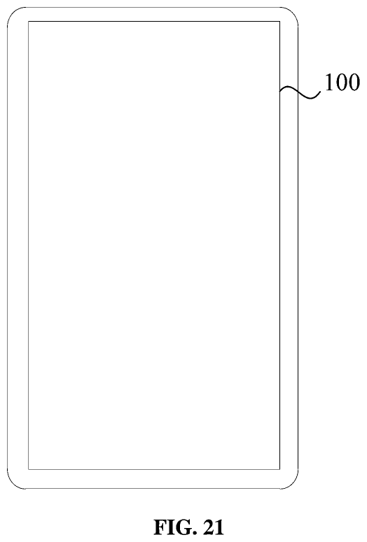

On the basis of the inventive concept as described above, embodiments of the present application further provide a display device. FIG. 21 is a structural diagram of a display device according to embodiments of the present application. As shown in FIG. 21, the display device includes the display panel 100 in the preceding embodiments. The display device includes the display panel 100 of any embodiment of the present application. Therefore, the display device provided in the embodiments of the present application has the corresponding beneficial effects of the display panel 100 provided in the embodiments of the present application. The details are not repeated here. Exemplarily, the display device may be an electronic device such as a mobile phone, a computer, a smart wearable device (for example, a smart watch) or an in-vehicle display device, which is not limited in the embodiment of the present application.

It is to be noted that the preceding are preferred embodiments of the present application and technical principles used therein. It is to be understood by those skilled in the art that the present application is not limited to the embodiments described herein. For those skilled in the art, various apparent modifications, adaptations and substitutions can be made without departing from the scope of the present application. Therefore, although the present application has been described in detail through the preceding embodiments, the present application is not limited to the preceding embodiments and may include other equivalent embodiments without departing from the concept of the present application. The scope of the present application is determined by the scope of the appended claims.

What is claimed is:

1. A display panel, comprising a display region and a plurality of subpixels located in the display region, wherein
the plurality of subpixels comprise pixel circuits, the display panel further comprises power signal lines located in the display region, and the power signal lines are electrically connected to the pixel circuits;
the power signal lines comprise first power signal lines and second power signal lines which are electrically connected, the first power signal lines extend in a first direction and are arranged in a second direction, and the second power signal lines extend in the second direction and are arranged in the first direction, wherein the first direction intersects the second direction;
the display panel further comprises a non-display region located on a side of the display region and a first power bus line located in the non-display region, wherein the first power signal lines are electrically connected to the first power bus line;
among two second power signal lines of the second power signal lines, a voltage in a second power signal line facing the first power bus line is different from a voltage in a second power signal line facing away from the first power bus line.

2. The display panel according to claim 1, wherein the voltage in the second power signal line facing the first power bus line is smaller than the voltage in the second power signal line facing away from the first power bus line.

3. The display panel according to claim 1, wherein a signal transmitted on the second power signal lines is a fixed potential signal.

4. The display panel according to claim 1, further comprising a plurality of switch elements located in the display region and a plurality of switch signal lines located in the display region and a switch driver circuit located in the non-display region;
a first terminal of a switch element of the plurality of switch elements is electrically connected to a second power signal line of the second power signal lines, a second terminal of the switch element is electrically connected to a first power signal line of the first power signal lines, and a control terminal of the switch element is electrically connected to a switch signal line of the plurality of switch signal lines;
the switch signal line is electrically connected to the switch driver circuit and is configured to receive a switch signal provided by the switch driver circuit;
the switch element is configured to make the first power signal line electrically connect to the second power signal line under control of the switch signal; and
the switch element comprises a switch transistor.

5. The display panel according to claim 4, wherein the plurality of switch elements are arranged in an array in the first direction and the second direction;
among the plurality of switch elements, first terminals of switch elements arranged in the second direction are electrically connected to a same second power signal line of the second power signal lines, second terminals of the switch elements arranged in the second direction correspond to the first power signal lines and are electrically connected to the first power signal lines, and control terminals of the switch elements arranged in the second direction are electrically connected to a same switch signal line of the plurality switch signal lines.

6. The display panel according to claim 4, wherein a pixel circuit of the pixel circuits comprises a drive transistor and a data write transistor;
the display panel further comprises a data signal line, a first scan signal line and a scan driver circuit, the data signal line and the first scan signal line are located in the display region, and the scan driver circuit is located in the non-display region;
a first terminal of the data write transistor is electrically connected to the data signal line, a second terminal of the data write transistor is electrically connected to a first terminal of the drive transistor, and a control terminal of the data write transistor is electrically connected to the first scan signal line;
the first scan signal line is electrically connected to the scan driver circuit for receiving a first scan signal provided by the scan driver circuit; the data write transistor is configured to output a data signal provided by the data signal line to the first terminal of the drive transistor under control of the first scan signal;
the switch element also serves as the data write transistor, the switch signal line also serves as the first scan signal line, and the switch driver circuit also serves as the scan driver circuit; and
an enable stage of the first scan signal comprises a first enable stage and a second enable stage; in the first enable stage, the data signal is transmitted through the data write transistor to the first terminal of the drive transistor; in the second enable stage, a voltage signal provided by the second power signal line is transmitted through the data write transistor to the first terminal of the drive transistor.

7. The display panel according to claim 6, wherein the pixel circuit further comprises a threshold compensation transistor, and the display panel further comprises a second scan signal line located in the display region;
a first terminal of the threshold compensation transistor is electrically connected to a second terminal of the drive transistor, a second terminal of the threshold compensation transistor is electrically connected to a control terminal of the drive transistor, and a control terminal of the threshold compensation transistor is electrically connected to the second scan signal line;
the threshold compensation transistor is configured to compensate the drive transistor for a gate voltage under control of a second scan signal provided by the second scan signal line; and
an enable stage of the second scan signal overlaps the first enable stage in timing.

8. The display panel according to claim 4, wherein the pixel circuit comprises a first light emission control transistor and a drive transistor;
a subpixel of the plurality of subpixels further comprises a light-emitting device;
the display panel further comprises a light emission control signal line located in the display region and a light emission control circuit located in the non-display region;
a first terminal of the first light emission control transistor is electrically connected to a second terminal of the drive transistor, a second terminal of the first light emission control transistor is electrically connected to an anode of the light-emitting device, and a control terminal of the first light emission control transistor is electrically connected to the light emission control signal line;
the light emission control signal line is electrically connected to the light emission control circuit for receiving a light emission control signal provided by the light emission control circuit; the first light emission control transistor is configured to output a first power signal provided by the first power signal line to the anode of the light-emitting device under control of the light emission control signal; and
the second terminal of the switch element is electrically connected to the second terminal of the first light emission control transistor.

9. The display panel according to claim 4, wherein the pixel circuit comprises a second light emission control transistor and a drive transistor;
the display panel further comprises a light emission control signal line located in the display region and a light emission control circuit located in the non-display region;
a first terminal of the second light emission control transistor is electrically connected to the first power signal line, a second terminal of the second light emission control transistor is electrically connected to a first terminal of the drive transistor, and a control terminal of the second light emission control transistor is electrically connected to the light emission control signal line;
the light emission control signal line is electrically connected to the light emission control circuit for receiving a light emission control signal provided by the light emission control circuit; the second light emission control transistor is configured to output a first power signal provided by the first power signal line to the first terminal of the drive transistor under control of the light emission control signal; and
the second terminal of the switch element is electrically connected to the first terminal of the second light emission control transistor.

10. The display panel according to claim 8, wherein the switch signal line also serves as the light emission control signal line, and the switch driver circuit also serves as the light emission control circuit.

11. The display panel according to claim 10, wherein the light emission control signal line comprises a main body portion and an extension portion which are connected, at least part of the main body portion extends in the second direction, and at least part of the extension portion extends in the first direction;
the extension portion overlaps an active portion of the switch element as the control terminal of the switch element.

12. The display panel according to claim 1, wherein the display panel comprises a plurality of signal line groups, each signal line group of the plurality of signal line groups comprises at least one second power signal line of the second power signal lines;
in a same signal line group of the plurality of signal line groups, a power signal in the at least one second power signal line has a same voltage; and
among at least two signal line groups of the plurality of signal line groups, a voltage of a power signal in a second power signal line in a signal line group facing the first power bus line is smaller than a voltage of a power signal in a second power signal line in a signal line group facing away from the first power bus line.

13. The display panel according to claim 12, wherein the each signal line group of the plurality of signal line groups comprises one second power signal line of the second power signal lines; or
the each signal line group of the plurality of signal line groups comprises at least two second power signal lines of the second power signal lines.

14. The display panel according to claim 13, wherein the each signal line group of the plurality of signal line groups comprises at least two second power signal lines of the second power signal lines, the at least two signal line groups comprise a first signal line group and a second signal line group, and the first signal line group is located on a side of the second signal line group facing the first power bus line; and
a number of second power signal lines in the first signal line group is larger than a number of second power signal lines in the second signal line group.

15. The display panel according to claim 12, wherein the plurality of signal line groups comprise a third signal line group, a fourth signal line group and a fifth signal line group, and the third signal line group, the fourth signal line group and the fifth signal line group are disposed adjacent to one another in the first direction;
the third signal line group is located on a side of the fourth signal line group facing the first power bus line, and the fourth signal line group is located on a side of the fifth signal line group facing the first power bus line;
a first difference exists between a voltage of a power signal in a second power signal line in the fourth signal line group and a voltage of a power signal in a second power signal line in the third signal line group, and a second difference exists between a voltage of a power signal in a second power signal line in the fifth signal line group and the voltage of the power signal in the second power signal line in the fourth signal line group; and
the first difference is equal to the second difference, or the first difference is less than the second difference.

16. The display panel according to claim 12, wherein the display panel further comprises a power signal terminal group located in the non-display region; and
the plurality of signal line groups are electrically connected to the power signal terminal group correspondingly.

17. The display panel according to claim 16, wherein the power signal terminal group comprises a plurality of power signal terminals, and power signals transmitted in different power signal terminals of the plurality of power signal terminals have different voltages; and
signal line groups of the plurality of signal line groups and having different voltages are electrically connected to different power signal terminals of the plurality of power signal terminals.

18. The display panel according to claim 16, wherein the power signal terminal group comprises at least one power signal terminal, and a number of the at least one power signal terminal is smaller than a number of the plurality of signal line groups; and
at least two signal line groups of the plurality of signal line groups are electrically connected to a same power signal terminal of the at least one power signal terminal for receiving power signals in a time division manner, wherein the power signals have different voltages and are transmitted by the same power signal terminal.

19. The display panel according to claim 18, wherein the display panel further comprises a de-multiplexing circuit located in the non-display region and de-multiplexing signal lines located in the non-display region; and
an input terminal of the de-multiplexing circuit is electrically connected to a power signal terminal of the at least one power signal terminal, output terminals of the de-multiplexing circuit are electrically connected to the at least two signal line groups, and control terminals of the de-multiplexing circuit are electrically connected to the de-multiplexing signal lines; the de-multiplexing circuit is configured to transmit a power signal transmitted by the power signal terminal to different signal line groups in a time division manner under control of a de-multiplexing control signal provided by the de-multiplexing signal lines, and a number of the input terminal of the de-multiplexing circuit is smaller than a number of the output terminals of the de-multiplexing circuit.

20. A display device, comprising a display panel; wherein the display panel comprises a display region and a plurality of subpixels located in the display region, wherein
the plurality of subpixels comprise pixel circuits, the display panel further comprises power signal lines located in the display region, and the power signal lines are electrically connected to the pixel circuits;
the power signal lines comprise first power signal lines and second power signal lines which are electrically connected, the first power signal lines extend in a first direction and are arranged in a second direction, and the second power signal lines extend in the second direction and are arranged in the first direction, wherein the first direction intersects the second direction;
the display panel further comprises a non-display region located on a side of the display region and a first power bus line located in the non-display region, wherein the first power signal lines are electrically connected to the first power bus line;
among two second power signal lines of the second power signal lines, a voltage in a second power signal line facing the first power bus line is different from a voltage in a second power signal line facing away from the first power bus line.
